(19) United States
(12) Patent Application Publication
(10) Pub. No.: US 2025/0144664 A1
(43) Pub. Date: May 8, 2025

(54) DEPOSITION MASK AND METHOD FOR MANUFACTURING THE SAME

(71) Applicant: Samsung Display Co., LTD., Yongin-si (KR)

(72) Inventors: Jeong Kuk KIM, Yongin-si (KR); Sung Won CHO, Yongin-si (KR); Jun Ho JO, Yongin-si (KR)

(73) Assignee: Samsung Display Co., LTD., Yongin-si (KR)

(21) Appl. No.: 18/748,753

(22) Filed: Jun. 20, 2024

(30) Foreign Application Priority Data
Nov. 6, 2023 (KR) 10-2023-0151731

(51) Int. Cl. B05C 21/00; H10K 59/12

(52) U.S. Cl. CPC B05C 21/005; H10K 59/12

(57) ABSTRACT

A deposition mask includes a silicon substrate including cell areas and a mask frame area excluding the cell areas, the mask frame area including a mask rip area partitioning the cell areas and an outer frame area disposed at an outermost portion of the silicon substrate, a mask rip disposed in the mask rip area, a mask membrane disposed in each of the cell areas, a first metal frame disposed in the outer frame area, and a second metal frame surrounding an outer portion of the silicon substrate and connected to the first metal frame.

### CROSS-REFERENCE TO RELATED APPLICATION(S)

This application claims priority to and benefits of Korean Patent Application No. 10-2023-0151731 under 35 U.S.C. § 119 filed on Nov. 6, 2023 in the Korean Intellectual Property Office, the entire contents of which are incorporated herein by reference.

### BACKGROUND

### 1. Technical Field

The disclosure relates to a deposition mask and a method for manufacturing the same.

### 2. Description of the Related Art

A wearable device that is developed in the form of glasses or a helmet and focuses on a distance close to the user's eyes is being developed. For example, the wearable device may be a head mounted display (HMD) device or AR glass. Such a wearable device provides a user with an augmented reality (hereinafter, referred to as “AR”) screen or a virtual reality (hereinafter, referred to as “VR”) screen.

The wearable device such as the HMD device or the AR glass may require a display specification of at least 2000 pixels per inch (PPI) to allow the user to use the device for a long time without feeling dizzy. To this end, organic light emitting diode on silicon (OLEDoS) technology, which is a small organic light emitting display device with high resolution, is emerging. The OLEDoS is a technology that disposes organic light emitting diodes (OLEDs) on a semiconductor wafer substrate on which a complementary metal oxide semiconductor (CMOS) is disposed.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

Aspects of the disclosure provide a deposition mask capable of manufacturing a high-resolution display panel by forming a mask membrane on a silicon substrate and a method for manufacturing the same.

Aspects of the disclosure also provide a deposition mask that enables the deposition mask to be attached to a substrate to be deposited without a separate structure inside a deposition device and a method for manufacturing the same.

Aspects of the disclosure also provide a deposition mask capable of increasing alignment accuracy and preventing mura defects due to sagging of the mask and a method for manufacturing the same.

According to an embodiment, a deposition mask may include a silicon substrate including a plurality of cell areas and a mask frame area excluding the plurality of cell areas, the mask frame area including a mask rip area partitioning the plurality of cell areas and an outer frame area disposed at an outermost portion of the silicon substrate; a mask rip disposed in the mask rip area; a mask membrane disposed in each of the plurality of cell areas; a first metal frame disposed in the outer frame area; and a second metal frame surrounding an outer portion of the silicon substrate and connected to the first metal frame.

The silicon substrate may have a substantially circular shape in plan view, and the second metal frame has a substantially ring shape surrounding the outer portion of the silicon substrate.

The silicon substrate may include a frame opening exposing a lower surface of the first metal frame in the outer frame area, and the second metal frame is connected to the first metal frame through the frame opening.

The first metal frame and the second metal frame may be connected to each other by welding.

A welded portion where the welding is performed may be continuously connected along a perimeter of the second metal frame.

A welded portion where the welding is performed may be discontinuously connected along a perimeter of the second metal frame.

The deposition mask may further include at least one metal sheet that crosses the silicon substrate. Both ends of the metal sheet may each be connected to the second metal frame.

The metal sheet may extend along the mask rip area at a lower portion of the silicon substrate, and the second metal frame may include a lower step portion on which the metal sheet is seated.

The metal sheet may extend along the mask rip area at a lower portion of the silicon substrate, and a groove into which the metal sheet is inserted is disposed on a side surface of the second metal frame.

The metal sheet may extend along the mask rip area at an upper portion of the silicon substrate, and the second metal frame may include an upper step portion on which the metal sheet is seated.

A thickness of the first metal frame may be greater than a thickness of the mask membrane.

The mask membrane may include a plating film.

The mask rip may be formed as a portion of the silicon substrate.

The mask rip may include a plating film formed by a same process as the mask membrane.

The mask rip may include a stacked structure of a portion of the silicon substrate and a plating film formed by a same process as the mask membrane.

A method for manufacturing a deposition mask may include preparing a silicon substrate including a plurality of cell areas and a mask frame area excluding the plurality of cell areas, the mask frame area including a mask rip area partitioning the plurality of cell areas and an outer frame area disposed at an outermost portion of the silicon substrate; forming a mask membrane and a first metal frame by performing a plating process; forming a cell opening corresponding to the plurality of cell areas and a frame opening exposing a lower surface of the first metal frame by etching a rear surface of the silicon substrate; aligning a second metal frame surrounding an outer portion of the silicon substrate with the silicon substrate; and connecting the first metal frame and the second metal frame to each other.

The silicon substrate has a substantially circular shape in plan view, and the second metal frame has a substantially ring shape surrounding the outer portion of the silicon substrate.

The connecting of the first metal frame and the second metal frame to each other may include a welding process.

A welded portion where the welding process may be performed continuously connected along a perimeter of the second metal frame.

A welded portion where the welding process may be performed discontinuously connected along a perimeter of the second metal frame.

According to the deposition mask and the method for manufacturing the same according to embodiments, the high-resolution display panel may be manufactured by forming the mask membrane on the silicon substrate.

The deposition mask may be attached to the substrate to be deposited without the separate structure inside the deposition device.

The alignment accuracy may be increased, and the mura defects due to the sagging of the mask may be prevented.

### BRIEF DESCRIPTION OF THE DRAWINGS

The above and other aspects and features of the disclosure will become more apparent by describing in detail embodiments thereof with reference to the attached drawings, in which:

FIG. 1 is a schematic perspective view illustrating a head mounted display device according to an embodiment;

FIG. 2 is an exploded perspective view illustrating an example of the head mounted display device of FIG. 1;

FIG. 3 is a schematic perspective view illustrating a head mounted display device according to an embodiment;

FIG. 4 is an exploded perspective view illustrating a display device according to an embodiment;

FIG. 5 is a schematic cross-sectional view illustrating an example in which a portion of a display panel is cut according to an embodiment;

FIG. 6 is a schematic perspective view of a mask according to an embodiment;

FIG. 7 is a schematic plan view of the mask according to an embodiment;

FIG. 8 is a flowchart illustrating a method for manufacturing a mask according to an embodiment;

FIGS. 9 to 13 are schematic cross-sectional process views for describing a method for manufacturing a mask according to an embodiment;

FIG. 14 is a schematic plan view of a mask for describing a position of a welded portion between a silicon substrate and a second metal frame according to an embodiment;

FIG. 15 is a schematic plan view of a mask in which a position of a welded portion between the silicon substrate and the second metal frame is changed according to an embodiment;

FIG. 16 is a flowchart illustrating a method for manufacturing a mask according to an embodiment;

FIGS. 17 to 21 are schematic cross-sectional process views for describing a method for manufacturing a mask according to an embodiment;

FIG. 22 is a flowchart illustrating a method for manufacturing a mask according to an embodiment;

FIGS. 23 to 27 are schematic cross-sectional process views for describing a method for manufacturing a mask according to an embodiment;

FIG. 28 is a schematic plan view of a mask including a metal sheet according to an embodiment;

FIGS. 29 and 30 are schematic cross-sectional views of a mask in which a metal sheet is coupled (or connected) to a lower surface of a silicon substrate according to an embodiment;

FIG. 31 is a schematic cross-sectional view of a mask in which a metal sheet is coupled (or connected) to an upper surface of a silicon substrate according to an embodiment;

FIG. 32 is a schematic plan view of a mask including metal sheets according to an embodiment;

FIG. 33 is a conceptual view for describing a coupling (or connecting) of a first metal frame and a second metal frame using an adhesive;

FIG. 34 is a conceptual view for describing a coupling (or connecting) of a first metal frame and a second metal frame using a screw;

FIG. 35 is a schematic cross-sectional view of a mask in which the mask rip area has a stacked structure of silicon and metal on silicon according to an embodiment;

FIG. 36 is a schematic cross-sectional view of a mask for describing a thickness of a first metal frame according to an embodiment; and

FIGS. 37 and 38 are schematic cross-sectional views of a mask illustrating a metal pattern disposed in a dummy area between a first metal frame and an outermost cell opening according to an embodiment.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

It will also be understood that when a layer is referred to as being “on” another layer or substrate, it can be directly on the other layer or substrate, or intervening layers may also be present. The same reference numbers indicate the same components throughout the specification.

In the drawings, sizes, thicknesses, ratios, and dimensions of the elements may be exaggerated for ease of description and for clarity. Like numbers refer to like elements throughout.

As used herein, the singular forms, “a,” “an,” and “the” are intended to include the plural forms as well, unless the context clearly indicates otherwise.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

In the specification and the claims, the phrase “at least one of” is intended to include the meaning of “at least one selected from the group of” for the purpose of its meaning and interpretation. For example, “at least one of A and B” may be understood to mean “A, B, or A and B.”

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the disclosure. Similarly, the second element could also be termed the first element.

The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

The terms “face” and “facing” mean that a first element may directly or indirectly oppose a second element. In a case in which a third element intervenes between the first and second element, the first and second element may be understood as being indirectly opposed to one another, although still facing each other.

When an element is described as ‘not overlapping’ or ‘to not overlap’ another element, this may include that the elements are spaced apart from each other, offset from each other, or set aside from each other or any other suitable term as would be appreciated and understood by those of ordinary skill in the art.

The terms “comprises,” “comprising,” “includes,” and/or “including,” “has,” “have,” and/or “having,” and variations thereof when used in this specification, specify the presence of stated features, integers, steps, operations, elements, components, and/or groups thereof, but do not preclude the presence or addition of one or more other features, integers, steps, operations, elements, components, and/or groups thereof.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Unless otherwise defined or implied herein, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

It will be understood that when an element (or a region, a layer, a portion, or the like) is referred to as “being on”, “connected to” or “coupled to” another element in the specification, it can be directly disposed on, connected or coupled to another element mentioned above, or intervening elements may be disposed therebetween.

It will be understood that the terms “connected to” or “coupled to” may include a physical or electrical connection or coupling.

Features of each of various embodiments of the disclosure may be partially or entirely combined with each other and may technically variously interwork with each other, and respective embodiments may be implemented independently of each other or may be implemented together in association with each other.

Hereinafter, embodiments will be described with reference to the accompanying drawings.

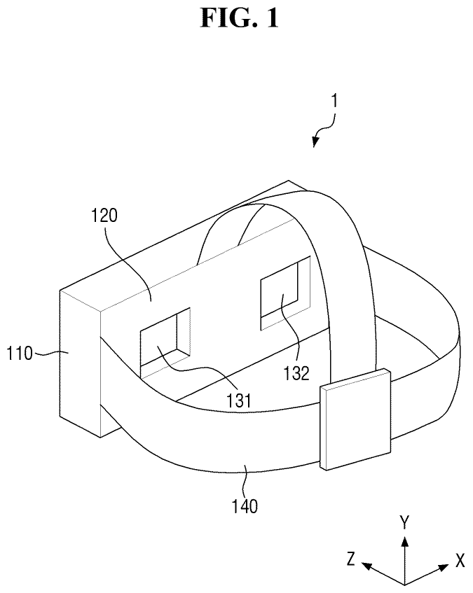

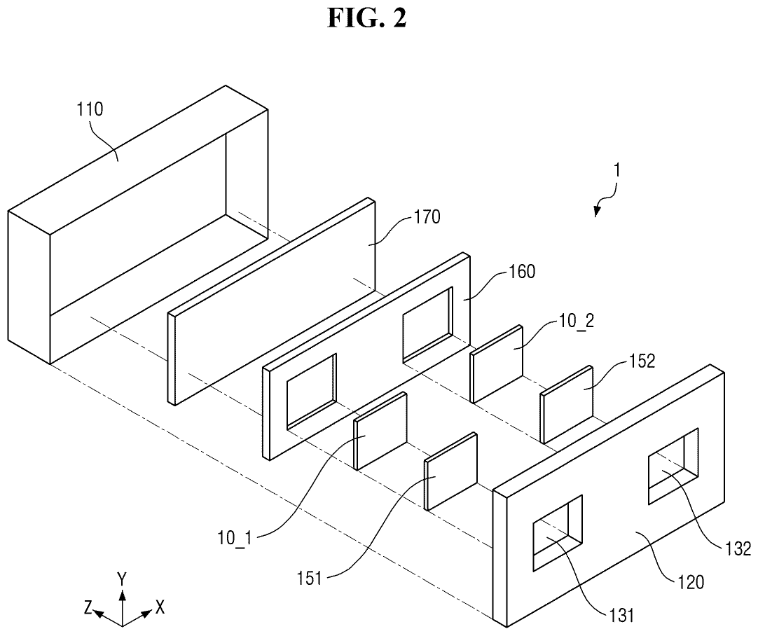

FIG. 1 is a schematic perspective view illustrating a head mounted display device according to an embodiment. FIG. 2 is an exploded perspective view illustrating an example of the head mounted display device of FIG. 1.

Referring to FIGS. 1 and 2, a head mounted display device 1 according to an embodiment may include a first display device 10_1, a second display device 10_2, a display device accommodating portion 110, an accommodating portion cover 120, a first eyepiece 131, a second eyepiece 132, a head mounting band 140, a middle frame 160, a first optical member 151, a second optical member 152, a control circuit board 170, and a connector.

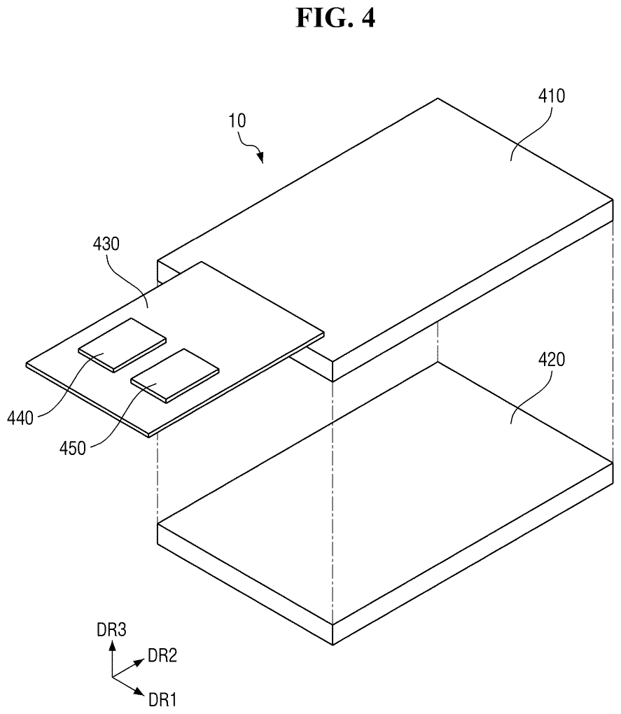

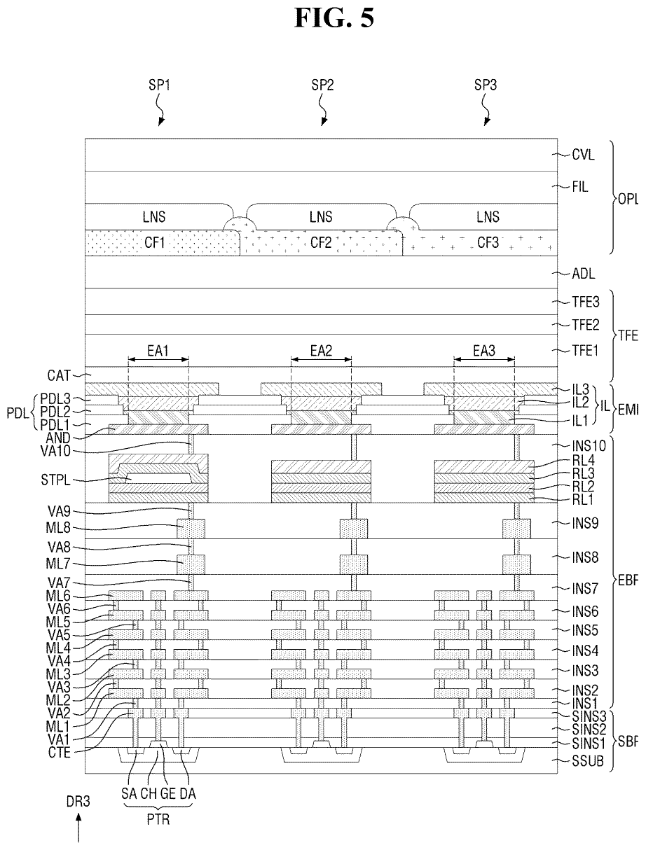

The first display device 10_1 provides an image to the user's left eye, and the second display device 10_2 provides an image to the user's right eye. Each of the first display device 10_1 and the second display device 10_2 is substantially the same as a display device 10 described with reference to FIGS. 4 and 5. Accordingly, descriptions of the first display device 10_1 and the second display device 10_2 will be replaced with descriptions with reference to FIGS. 4 and 5.

The first optical member 151 may be disposed between the first display device 10_1 and the first eyepiece 131. The second optical member 152 may be disposed between the second display device 10_2 and the second eyepiece 132. Each of the first optical member 151 and the second optical member 152 may include at least one convex lens.

The middle frame 160 may be disposed between the first display device 10_1 and the control circuit board 170 and may be disposed between the second display device 10_2 and the control circuit board 170. The middle frame 160 serves to support and fix the first display device 10_1, the second display device 10_2, and the control circuit board 170.

The control circuit board 170 may be disposed between the middle frame 160 and the display device accommodating portion 110. The control circuit board 170 may be connected to the first display device 10_1 and the second display device 10_2 through the connector. The control circuit board 170 may convert an image source input from the outside into digital video data DATA, and may transmit the digital video data DATA to the first display device 10_1 and the second display device 10_2 through the connector.

The control circuit board 170 may transmit digital video data DATA corresponding to a left eye image optimized for the user's left eye to the first display device 10_1, and may transmit digital video data DATA corresponding to a right eye image optimized for the user's right eye to the second display device 10_2. By way of example, the control circuit board 170 may transmit the same digital video data DATA to the first display device 10_1 and the second display device 10_2.

The display device accommodating portion 110 serves to accommodate the first display device 10_1, the second display device 10_2, the middle frame 160, the first optical member 151, the second optical member 152, the control circuit board 170, and the connector. The accommodating portion cover 120 is disposed to cover one opened surface of the display device accommodating portion 110. The accommodating portion cover 120 may include a first eyepiece 131 where the user's left eye is disposed and a second eyepiece 132 where the user's right eye is disposed. It is illustrated in FIGS. 1 and 2 that the first eyepiece 131 and the second eyepiece 132 are separately disposed, but embodiments of the specification are not limited thereto. The first eyepiece 131 and the second eyepiece 132 may be integrated into one.

The first eyepiece 131 may be aligned with the first display device 10_1 and the first optical member 151, and the second eyepiece 132 may be aligned with the second display device 10_2 and the second optical member 152. Therefore, the user may view an image of the first display device 10_1 magnified as a virtual image by the first optical member 151 through the first eyepiece 131, and may view an image of the second display device 10_2 magnified as a virtual image by the second optical member 152 through the second eyepiece 132.

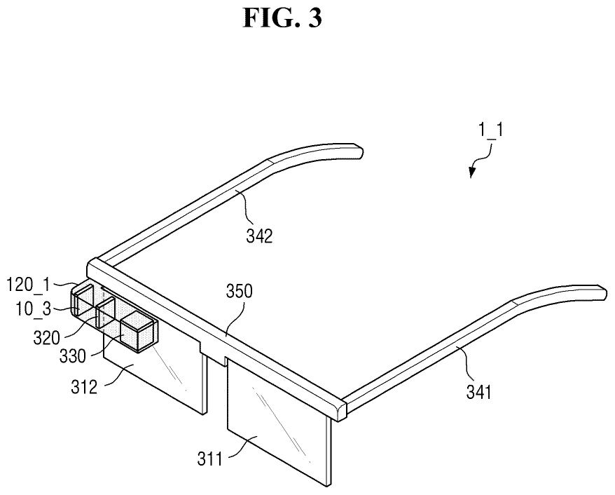

The head mounting band 140 serves to fix the display device accommodating portion 110 to a user's head so that the first eyepiece 131 and the second eyepiece 132 of the accommodating portion cover 120 are disposed on the user's left and right eyes, respectively. In case that the display device accommodating portion 110 is implemented in a lightweight and small size, the head mounted display device 1 may include eyeglass frames as illustrated in FIG. 3 instead of the head mounting band 140.

The head mounted display device 1 may further include a battery for supplying power, an external memory slot for accommodating an external memory, and an external connection port and a wireless communication module for receiving an image source. The external connection port may be a universe serial bus (USB) terminal, a display port, or a high-definition multimedia interface (HDMI) terminal, and the wireless communication module may be a 5G communication module, a 4G communication module, a Wi-Fi module, or a Bluetooth module.

FIG. 3 is a schematic perspective view illustrating a head mounted display device according to an embodiment.

Referring to FIG. 3, a head mounted display device 1_1 according to an embodiment may be a glasses-type display device in which a display device accommodating portion 120_1 is implemented in a lightweight and small size. The head mounted display device 1_1 according to an embodiment may include a display device 10_3, a left eye lens 311, a right eye lens 312, a support frame 350, eyeglass frame legs 341 and 342, an optical member 320, a light path conversion member 330, and a display device accommodating portion 120_1.

The display device 10_3 illustrated in FIG. 3 is substantially the same as the display device 10 described with reference to FIGS. 4 and 5. Accordingly, descriptions of the first display device 10_1 and the second display device 10_2 will be replaced with descriptions with reference to FIGS. 4 and 5.

The display device accommodating portion 120_1 may include the display device 10_3, the optical member 320, and the light path conversion member 330. As an image displayed on the display device 10_3 is magnified by the optical member 320 and a light path thereof is converted by the light path conversion member 330, the image may be provided to the user's right eye through the right eye lens 312. Accordingly, the user may view an augmented reality image in which a virtual image displayed on the display device 10_3 and a real image viewed through the right eye lens 312 are combined through the right eye.

It is illustrated in FIG. 3 that the display device accommodating portion 120_1 is disposed at a right distal end of the support frame 350, but the specification is not limited thereto. For example, the display device accommodating portion 120_1 may be disposed at a left distal end of the support frame 350, and in this case, the image of the display device 10_3 may be provided to the user's left eye. By way of example, the display device accommodating portions 120_1 may be disposed at both the left and right distal ends of the support frame 350. In this case, the user may view the image displayed on the display device 10_3 through both the user's left and right eyes.

FIG. 4 is an exploded perspective view illustrating a display device according to an embodiment.

Referring to FIG. 4, a display device 10 according to an embodiment is a device that displays a moving image or a still image. The display device 10 according to an embodiment may be applied to portable electronic devices such as a mobile phone, a smart phone, a tablet personal computer (PC), a mobile communication terminal, an electronic notebook, an electronic book, a portable multimedia player (PMP), navigation, and an ultra mobile PC (UMPC). For example, the display device 10 may be applied to a display unit of a television, a laptop computer, a monitor, a billboard, or the Internet of Things (IoT). By way of example, the display device 10 may be applied to a smart watch, a watch phone, and a head mounted display (HMD) for implementing virtual reality and augmented reality.

The display device 10 according to an embodiment may include a display panel 410, a heat dissipation layer 420, a circuit board 430, a driving circuit 440, and a power supply circuit 450.

The display panel 410 may be formed in a planar shape similar to a quadrangle. For example, the display panel 410 may have a planar shape similar to a quadrangle having short sides in a first direction DR1 (or X) and long sides in a second direction DR2 (or Y) intersecting the first direction DR1. In the display panel 410, a corner where the short side in the first direction DR1 and the long side in the second direction DR2 meet may be rounded to have a selectable curvature or may be formed at a right angle. The planar shape of the display panel 410 is not limited to the quadrangle, and may be formed similarly to other polygons, circles, or ovals. A planar shape of the display device 10 may follow the planar shape of the display panel 410, but the specification is not limited thereto.

The display panel 410 may include a display area that displays an image and a non-display area that does not display an image.

The display area may include pixels, and each of the pixels may include sub-pixels (SP1, SP2, and SP3 in FIG. 5). The sub-pixels SP1, SP2, and SP3 include pixel transistors. The pixel transistors may be formed through a semiconductor process and may be disposed on a semiconductor substrate (SSUB in FIG. 5). For example, the pixel transistors may be formed of a complementary metal oxide semiconductor (CMOS).

The heat dissipation layer 420 may overlap the display panel 410 in a third direction DR3 (or Z), which is a thickness direction of the display panel 410. The heat dissipation layer 420 may be disposed on one surface or a surface of the display panel 410, for example, a rear surface thereof. The heat dissipation layer 420 serves to dissipate heat generated from the display panel 410. The heat dissipation layer 420 may include a metal layer such as graphite, silver (Ag), copper (Cu), or aluminum (Al) having high thermal conductivity.

The circuit board 430 may be electrically connected to pads PD of a pad area PDA of the display panel 410 by using a conductive adhesive member such as an anisotropic conductive film. The circuit board 430 may be a flexible printed circuit board or flexible film made of a flexible material. It is illustrated in FIG. 4 that the circuit board 430 is unfolded, but the circuit board 430 may be bent. In this case, one end or an end of the circuit board 430 may be disposed on the rear surface of the display panel 410. One end or an end of the circuit board 430 may be an opposite end of the other end or another end of the circuit board 430 connected to the pads PD of the pad area PDA of the display panel 410 by using a conductive adhesive member.

The driving circuit 440 may receive digital video data and timing signals from the outside. The driving circuit 440 may generate a scan timing control signal, an emission timing control signal, and a data timing control signal for controlling the display panel 410 according to the timing signals.

The power supply circuit 450 may generate panel driving voltages according to a power voltage from the outside.

The driving circuit 440 and the power supply circuit 450 may be each formed as an integrated circuit (IC) and attached to one surface or a surface of the circuit board 430.

FIG. 5 is a schematic cross-sectional view illustrating an example in which a portion of a display panel is cut according to an embodiment. For example, FIG. 5 illustrates a partial cross-sectional structure of a display area including sub-pixels (SP1, SP2, and SP3 in FIG. 5).

Referring to FIG. 5, the display panel 410 may include a semiconductor backplane SBP, a light emitting element backplane EBP, a light emitting clement layer EMI, an encapsulation layer TFE, an optical layer OPL, a cover layer CVL, and a polarizing plate (not illustrated).

The semiconductor backplane SBP may include a semiconductor substrate SSUB including pixel transistors PTR, semiconductor insulating films covering the pixel transistors PTR, and contact terminals CTE electrically connected to the pixel transistors PTR, respectively.

The semiconductor substrate SSUB may be a silicon substrate, a germanium substrate, or a silicon-germanium substrate. The semiconductor substrate SSUB may be a substrate doped with first-type impurities. Well areas WA may be disposed on an upper surface of the semiconductor substrate SSUB. The well areas WA may be areas doped with second-type impurities. The second type impurity may be different from the first type impurity described above. For example, in case that the first-type impurity is a p-type impurity, the second-type impurity may be an n-type impurity. By way of example, in case that the first-type impurity is an n-type impurity, the second-type impurity may be a p-type impurity.

Each of the well areas WA may include a source area SA corresponding to a source electrode of the pixel transistor PTR, a drain area DA corresponding to a drain electrode thereof, and a channel area CH disposed between the source area SA and the drain area DA.

Each of the source area SA and the drain area DA may be an area doped with first-type impurities. A gate electrode GE of the pixel transistor PTR may overlap the well area WA in the third direction DR3. The channel area CH may overlap the gate electrode GE in the third direction DR3. The source area SA may be disposed on one side or a side of the gate electrode GE, and the drain area DA may be disposed on the other side of the gate electrode GE.

Each of the well areas WA further may include a first low-concentration impurity area LDD1 disposed between the channel area CH and the source area SA and a second low-concentration impurity area LDD2 disposed between the channel area CH and the drain area DA. The first low-concentration impurity area LDD1 may be an area having an impurity concentration lower than that of the source area SA. The second low-concentration impurity area LDD2 may be an area having an impurity concentration lower than that of the drain area DA. A distance between the source area SA and the drain area DA may be increased by the first low-concentration impurity area LDD1 and the second low-concentration impurity area LDD2. Therefore, since a length of the channel area CH of each of the pixel transistors PTR may increase, punch-through and hot carrier phenomena caused by a short channel may be prevented.

A first semiconductor insulating film SINS1 may be disposed on the semiconductor substrate SSUB. The first semiconductor insulating film SINS1 may be formed as a silicon nitride (SiCN) or silicon oxide (SiOₓ)-based inorganic film, but an embodiment of the specification is not limited thereto.

A second semiconductor insulating film SINS2 may be disposed on the first semiconductor insulating film SINS1. The second semiconductor insulating film SINS2 may be formed as a silicon oxide (SiOₓ)-based inorganic film, but an embodiment of the specification is not limited thereto.

Contact terminals CTE may be disposed on the second semiconductor insulating film SINS2. Each of the contact terminals CTE may be connected to any one of the gate electrode GE, the source area SA, and the drain area DA of each of the pixel transistors PTR through a hole penetrating through the first semiconductor insulating film SINS1 and the second semiconductor insulating film SINS2. The contact terminals CTE may be formed of any one of copper (Cu), aluminum (Al), tungsten (W), molybdenum (Mo), chromium (Cr), gold (Au), titanium (Ti), nickel (Ni), and neodymium (Nd), or an alloy including any one thereof.

A third semiconductor insulating film SINS3 may be disposed on a side surface of each of the contact terminals CTE. An upper surface of each of the contact terminals CTE may be exposed without being covered by the third semiconductor insulating film SINS3. The third semiconductor insulating film SINS3 may be formed as a silicon oxide (SiOₓ)-based inorganic film, but the disclosure is not limited thereto.

The semiconductor substrate SSUB may be replaced with a glass substrate or a polymer resin substrate such as polyimide. In this case, thin film transistors may be disposed on the glass substrate or the polymer resin substrate. The glass substrate may be a rigid substrate that is not bent, and the polymer resin substrate may be a flexible substrate that may be bent or curved.

The light emitting element backplane EBP may include first to eighth metal layers ML1 to ML8, reflective metal layers RL1 to RLA, vias VA1 to VA10, and a step layer STPL. The light emitting element backplane EBP may include interlayer insulating films INS1 to INS10 disposed between the first to sixth metal layers ML1 to ML6.

The first to eighth metal layers ML1 to ML8 serve to implement a circuit of a first sub-pixel SP1 by connecting the contact terminals CTE exposed from the semiconductor backplane SBP.

A first interlayer insulating film INS1 may be disposed on the semiconductor backplane SBP. Each of the first vias VA1 may penetrate through the first interlayer insulating film INS1 and be connected to the contact terminal CTE exposed from the semiconductor backplane SBP. Each of the first metal layers ML1 may be disposed on the first interlayer insulating film INS1 and may be connected to the first via VA1.

A second interlayer insulating film INS2 may be disposed on the first interlayer insulating film INS1 and the first metal layers ML1. Each of the second vias VA2 may be connected to the first metal layer ML1 exposed by penetrating through the second interlayer insulating film INS2. Each of the second metal layers ML2 may be disposed on the second interlayer insulating film INS2 and may be connected to the second via VA2.

A third interlayer insulating film INS3 may be disposed on the second interlayer insulating film INS2 and the second metal layers ML2. Each of the third vias VA3 may be connected to the second metal layer ML2 exposed by penetrating through the third interlayer insulating film INS3. Each of the third metal layers ML3 may be disposed on the third interlayer insulating film INS3 and may be connected to the third via VA3.

A fourth interlayer insulating film INS4 may be disposed on the third interlayer insulating film INS3 and the third metal layers ML3. Each of the fourth vias VA4 may be connected to the third metal layer ML3 exposed by penetrating through the fourth interlayer insulating film INS4. Each of the fourth metal layers ML4 may be disposed on the fourth interlayer insulating film INS4 and may be connected to the fourth via VA4.

A fifth interlayer insulating film INS5 may be disposed on the fourth interlayer insulating film INS4 and the fourth metal layers ML4. Each of the fifth vias VA5 may be connected to the fourth metal layer MLA exposed by penetrating through the fifth interlayer insulating film INS5. Each of the fifth metal layers ML5 may be disposed on the fifth interlayer insulating film INS5 and may be connected to the fifth via VA5.

A sixth interlayer insulating film INS6 may be disposed on the fifth interlayer insulating film INS5 and the fifth metal layers ML5. Each of the sixth vias VA6 may be connected to the fifth metal layer ML5 exposed by penetrating through the sixth interlayer insulating film INS6. Each of the sixth metal layers ML6 may be disposed on the sixth interlayer insulating film INS6 and may be connected to the sixth via VA6.

A seventh interlayer insulating film INS7 may be disposed on the sixth interlayer insulating film INS6 and the sixth metal layers ML6. Each of the seventh vias VA7 may be connected to the sixth metal layer ML6 exposed by penetrating through the seventh interlayer insulating film INS7. Each of the seventh metal layers ML7 may be disposed on the seventh interlayer insulating film INS7 and may be connected to the seventh via VA7.

An eighth interlayer insulating film INS8 may be disposed on the seventh interlayer insulating film INS7 and the seventh metal layers ML7. Each of the eighth vias VA8 may be connected to the seventh metal layer ML7 exposed by penetrating through the eighth interlayer insulating film INS8. Each of the eighth metal layers ML8 may be disposed on the eighth interlayer insulating film INS8 and may be connected to the eighth via VA8.

The first to eighth metal layers ML1 to ML8 and the first to eighth vias VA1 to VA8 may be formed of substantially the same material. The first to eighth metal layers ML1 to ML8 and the first to eighth vias VA1 to VA8 may be formed of any one of copper (Cu), aluminum (Al), tungsten (W), molybdenum (Mo), chromium (Cr), gold (Au), titanium (Ti), nickel (Ni), and neodymium (Nd), or an alloy including any one thereof. The first to eighth vias VA1 to VA8 may be formed of substantially the same material. The first to eighth interlayer insulating films INS1 to INS8 may be formed as a silicon oxide (SiOₓ)-based inorganic film, but specification is not limited thereto.

A thickness of the first metal layer ML1, a thickness of the second metal layer ML2, a thickness of the third metal layer ML3, a thickness of the fourth metal layer ML4, a thickness of the fifth metal layer ML5, and a thickness of the sixth metal layer ML6 may be greater than a thickness of the first via VA1, a thickness of the second via VA2, a thickness of the third via VA3, a thickness of the fourth via VA4, a thickness of the fifth via VA5, and a thickness of the sixth via VA6, respectively. Each of the thickness of the second metal layer ML2, the thickness of the third metal layer ML3, the thickness of the fourth metal layer ML4, the thickness of the fifth metal layer ML5, and the thickness of the sixth metal layer ML6 may be greater than the thickness of the first metal layer ML1. The thickness of the second metal layer ML2, the thickness of the third metal layer ML3, the thickness of the fourth metal layer ML4, the thickness of the fifth metal layer ML5, and the thickness of the sixth metal layer ML6 may be substantially the same.

Each of a thickness of the seventh metal layer ML7 and a thickness of the eighth metal layer ML8 may be greater than each of the thickness of the first metal layer ML1, the thickness of the second metal layer ML2, the thickness of the third metal layer ML3, the thickness of the fourth metal layer ML4, the thickness of the fifth metal layer ML5, and the thickness of the sixth metal layer ML6. Each of the thickness of the seventh metal layer ML7 and the thickness of the eighth metal layer ML8 may be greater than each of a thickness of the seventh via VA7 and a thickness of the eighth via VA8. Each of the thickness of the seventh via VA7 and the thickness of the eighth via VA8 may be greater than each of the thickness of the first via VA1, the thickness of the second via VA2, the thickness of the third via VA3, the thickness of the fourth via VA4, the thickness of the fifth via VA5, and the thickness of the sixth via VA6. The thickness of the seventh metal layer ML7 and the thickness of the eighth metal layer ML8 may be substantially the same.

A ninth interlayer insulating film INS9 may be disposed on the eighth interlayer insulating film INS8 and the eighth metal layers ML8. The ninth interlayer insulating film INS9 may be formed as a silicon oxide (SiOₓ)-based inorganic film, but the specification is not limited thereto.

Each of the ninth vias VA9 may be connected to the eighth metal layer ML8 exposed by penetrating through the ninth interlayer insulating film INS9. The ninth vias VA9 may be formed of any one of copper (Cu), aluminum (Al), tungsten (W), molybdenum (Mo), chromium (Cr), gold (Au), titanium (Ti), nickel (Ni), and neodymium (Nd), or an alloy including any one thereof.

Each of first reflective electrodes RL1 may be disposed on the ninth interlayer insulating film INS9 and may be connected to the ninth via VA9. The first reflective electrodes RL1 may be formed of any one of copper (Cu), aluminum (Al), tungsten (W), molybdenum (Mo), chromium (Cr), gold (Au), titanium (Ti), nickel (Ni), and neodymium (Nd), or an alloy including any one thereof.

Each of second reflective electrodes RL2 may be disposed on the first reflective electrode RL1. The second reflective electrodes RL2 may be formed of any one of copper (Cu), aluminum (Al), tungsten (W), molybdenum (Mo), chromium (Cr), gold (Au), titanium (Ti), nickel (Ni), and neodymium (Nd), or an alloy including any one thereof. For example, the second reflective electrodes RL2 may be formed of titanium nitride (TiN).

In the first sub-pixel SP1, a step layer STPL may be disposed on the second reflective electrode RL2. The step layer STPL may not be disposed in each of the second sub-pixel SP2 and the third sub-pixel SP3. A thickness of the step layer STPL may be set in consideration of a wavelength of light of a first color and a distance from a first light emitting layer EML1 to a fourth reflective electrode RL4 to be advantageous in reflecting the light of the first color emitted from the first light emitting layer EML1 of the first sub-pixel SP1. The step layer STPL may be formed of a silicon carbon nitride (SiCN) or silicon oxide (SiOₓ)-based inorganic film, but embodiments are not limited thereto.

In the first sub-pixel SP1, a third reflective electrode RL3 may be disposed on the second reflective electrode RL2 and the step layer STPL. In the second and third sub-pixels SP2 and SP3, the third reflective electrode RL3 may be disposed on the second reflective electrode RL2. The third reflective electrodes RL3 may be formed of any one of copper (Cu), aluminum (Al), tungsten (W), molybdenum (Mo), chromium (Cr), gold (Au), titanium (Ti), nickel (Ni), and neodymium (Nd), or an alloy including any one thereof.

At least one of the first reflective electrode RL1, the second reflective electrode RL2, and the third reflective electrode RL3 may be omitted.

Each of fourth reflective electrodes RL4 may be disposed on the third reflective electrode RL3. The fourth reflective electrodes RL4 may be layers that reflect light from first to third intermediate layers EML1, EML2, and EML3. The fourth reflective electrodes RL4 may include a metal having a high reflectance to be advantageous in reflecting light. The fourth reflective electrode RL4 may be formed of aluminum (Al), a stacked structure (Ti/Al/Ti) of aluminum and titanium, a stacked structure (ITO/Al/ITO) of aluminum and ITO, an APC alloy, which is an alloy of silver (Ag), palladium (Pd), and copper (Cu), and a stacked structure (ITO/APC/ITO) of an APC alloy and ITO, but the specification is not limited thereto.

A tenth interlayer insulating film INS10 may be disposed on the ninth interlayer insulating film INS9 and the fourth reflective electrode RLA. The tenth interlayer insulating film INS10 may be formed as a silicon oxide (SiOₓ)-based inorganic film, but the specification is not limited thereto.

Each of the tenth vias VA10 may be connected to the ninth metal layer ML9 exposed by penetrating through the tenth interlayer insulating film INS10. The tenth vias VA10 may be formed of any one of copper (Cu), aluminum (Al), tungsten (W), molybdenum (Mo), chromium (Cr), gold (Au), titanium (Ti), nickel (Ni), and neodymium (Nd), or an alloy including any one thereof. Due to the step layer STPL, a thickness of the tenth via VA10 in the first sub-pixel SP1 may be smaller than a thickness of the tenth via VA10 in each of the second and third sub-pixels SP2 and SP3.

The light emitting element layer EMI may be disposed on the light emitting element backplane EBP. The light emitting element layer EMI may include light emitting elements LE each including a first electrode AND, an intermediate layer IL, and a second electrode CAT, and a pixel defining film PDL.

The first electrode AND of each of the light emitting elements LE may be disposed on the tenth interlayer insulating film INS10 and may be connected to the tenth via VA10. The first electrode AND of each of the light emitting elements LE may be connected to the drain area DA or the source area SA of the pixel transistor PTR through the tenth via VA10, the first to fourth reflective electrodes RL1 to RL4, the first to ninth vias VA1 to VA9, the first to eighth metal layers ML1 to ML8, and the contact terminal CTE. The first electrode AND of each of the light emitting elements LE may be formed of any one of copper (Cu), aluminum (Al), tungsten (W), molybdenum (Mo), chromium (Cr), gold (Au), titanium (Ti), nickel (Ni), and neodymium (Nd), or an alloy including any one thereof. For example, the first electrode AND of each of the light emitting elements LE may be formed of titanium nitride (TiN).

The pixel defining film PDL may be disposed on a partial area of the first electrode AND of each of the light emitting elements LE. The pixel defining film PDL may cover an edge of the first electrode AND of each of the light emitting elements LE. The pixel defining film PDL serves to partition the first light emitting areas EA1, the second light emitting areas EA2, and the third light emitting areas EA3.

The first light emitting area EA1 may be defined as an area in which the first electrode AND, the intermediate layer IL, and the second electrode CAT are sequentially stacked in the first sub-pixel SP1 to emit light. The second light emitting area EA2 may be defined as an area in which the first electrode AND, the intermediate layer IL, and the second electrode CAT are sequentially stacked in the second sub-pixel SP2 to emit light. The third light emitting area EA3 may be defined as an area in which the first electrode AND, the intermediate layer IL, and the second electrode CAT are sequentially stacked in the third sub-pixel SP3 to emit light.

The pixel defining film PDL may include first to third pixel defining films PDL1, PDL2, and PDL3. The first pixel defining film PDL1 may be disposed on the edge of the first electrode AND of each of the light emitting elements LE, the second pixel defining film PDL2 may be disposed on the first pixel defining film PDL1, and the third pixel defining film PDL3 may be disposed on the second pixel defining film PDL2. The first pixel defining film PDL1, the second pixel defining film PDL2, and the third pixel defining film PDL3 may be formed as a silicon oxide (SiOₓ)-based inorganic film, but the specification is not limited thereto.

The intermediate layer IL may include a first intermediate layer IL1, a second intermediate layer IL2, and a third intermediate layer IL3.

The intermediate layer IL may have a tandem structure including intermediate layers IL1, IL2, and IL3 emitting different light. For example, the intermediate layer IL may include a first intermediate layer IL1 emitting light of a first color, a second intermediate layer IL2 emitting light of a third color, and a third intermediate layer IL3 emitting light of a second color. The first intermediate layer IL1, the second intermediate layer IL2, and the third intermediate layer IL3 may be sequentially stacked each other.

The first intermediate layer IL1 may have a structure in which a first hole transporting layer, a first organic light emitting layer emitting light of a first color, and a first electron transporting layer may be sequentially stacked each other. The second intermediate layer IL2 may have a structure in which a second hole transporting layer, a second organic light emitting layer emitting light of a third color, and a second electron transporting layer may be sequentially stacked each other. The third intermediate layer IL3 may have a structure in which a third hole transporting layer, a third organic light emitting layer emitting light of a second color, and a third electron transporting layer may be sequentially stacked each other.

The intermediate layer IL covers the first electrode AND at the opening of the pixel defining film PDL and covers the pixel defining film PDL between the sub-pixels SP1, SP2, and SP3 disposed to be adjacent to each other, and a portion thereof may be disconnected.

According to an embodiment, by disconnecting the intermediate layer IL between the sub-pixels SP1, SP2, and SP3 adjacent to each other, it is possible to prevent leakage current between the sub-pixels SP1, SP2, and SP3 adjacent to each other and prevent color crosstalk. The color crosstalk refers to, for example, a phenomenon in which a red sub-pixel adjacent to a blue sub-pixel unintentionally is turned on while the blue sub-pixel emits blue color. The color crosstalk occurs due to leakage current, and may occur in case that the blue sub-pixel and the red sub-pixel that have a large difference in voltage driving the pixels are adjacent to each other. For example, the leakage current is a phenomenon in which a portion of the driving current is transmitted to the red sub-pixel through at least a portion of a conductive layer of the intermediate layer IL while the driving current is supplied to the light emitting element LE of the blue sub-pixel to turn on the blue sub-pixel. In case that the leakage current occurs, the red sub-pixel may be unintentionally turned on while the blue sub-pixel is turned on.

The number of intermediate layers IL1, IL2, and IL3 emitting different light is not limited to that illustrated in FIG. 5. For example, the intermediate layer IL may include two intermediate layers. In this case, one of the two intermediate layers may be substantially the same as the first intermediate layer IL1, and the other thereof may include a second hole transporting layer, a second organic light emitting layer, a third organic light emitting layer, and a second electron transporting layer. In this case, a charge generation layer for supplying electrons to one intermediate layer and supplying charges to the other intermediate layer may be disposed between the two intermediate layers.

It is illustrated in FIG. 5 that the first to third intermediate layers IL1, IL2, and IL3 are all disposed in the first light emitting area EA1, the second light emitting area EA2, and the third light emitting area EA3, but the specification is not limited thereto. For example, the first intermediate layer IL1 may be disposed in the first light emitting area EA1 and may not be disposed in the second light emitting area EA2 and the third light emitting area EA3. The second intermediate layer IL2 may be disposed in the second light emitting area EA2 and may not be disposed in the first light emitting area EA1 and the third light emitting area EA3. The third intermediate layer IL3 may be disposed in the third light emitting area EA3 and may not be disposed in the first light emitting area EA1 and the second light emitting area EA2. In this case, first to third color filters CF1, CF2, and CF3 of the optical layer OPL may be omitted.

The second electrode CAT may be disposed on the third intermediate layer IL3. The second electrode CAT may be disposed on the third intermediate layer IL3 in each of the trenches TRC. The second electrode CAT may be formed of a transparent conductive material (TCO) such as ITO or IZO capable of transmitting light, or a semi-transmissive conductive material such as magnesium (Mg), silver (Ag), or an alloy of magnesium (Mg) and silver (Ag). In case that the second electrode CAT is formed of a semi-transmissive conductive material, light emission efficiency may be increased in each of the first to third sub-pixels SP1, SP2, and SP3 by micro cavities.

The encapsulation layer TFE may be disposed on the light emitting element layer EMI. The encapsulation layer TFE may include one or more inorganic films TFE1 and TFE2 to prevent oxygen or moisture from permeating into the light emitting element layer EMI. The encapsulation layer TFE may include at least one organic film to protect the light emitting clement layer EMI from foreign substances such as dust. For example, the encapsulation layer TFE may include a first encapsulation inorganic film TFE1, an encapsulation organic film TFE2, and a second encapsulation inorganic film TFE3.

The first encapsulation inorganic film TFE1 may be disposed on the second electrode CAT, the encapsulation organic film TFE2 may be disposed on the first encapsulation inorganic film TFE1, and the second encapsulation inorganic film TFE3 may be disposed on the encapsulation organic film TFE2. The first encapsulation inorganic film TFE1 and the second encapsulation inorganic film TFE3 may be formed as multiple films in which one or more inorganic films of a silicon nitride layer (SiNₓ), a silicon oxynitride layer (SiON), a silicon oxide layer (SiOₓ), a titanium oxide layer (TiOₓ), and an aluminum oxide layer (AlOₓ) are alternately stacked each other. The encapsulation organic film TFE2 may be a monomer. By way of example, the encapsulation organic film TFE2 may be an organic film made of an acrylic resin, an epoxy resin, a phenolic resin, a polyamide resin, or a polyimide resin.

An adhesive layer ADL may be a layer for adhering the encapsulation layer TFE and the optical layer OPL. The adhesive layer ADL may be a double-sided adhesive member. The adhesive layer ADL may be a transparent adhesive member such as a transparent adhesive or a transparent adhesive resin.

The optical layer OPL may include color filters CF1, CF2, and CF3, lenses LNS, and a filling layer FIL. The color filters CF1, CF2, and CF3 may include first to third color filters CF1, CF2, and CF3. The first to third color filters CF1, CF2, and CF3 may be disposed on the adhesive layer ADL.

The first color filter CF1 may overlap the first light emitting area EA1 of the first sub-pixel SP1. The first color filter CF1 may transmit light of a first color, for example, light in a blue wavelength band. The red wavelength band may be in a range of about 370 nm to about 460 nm. Therefore, the first color filter CF1 may transmit light of a first color among light emitted from the first light emitting area EA1.

The second color filter CF2 may overlap the second light emitting area EA2 of the second sub-pixel SP2. The second color filter CF2 may transmit light of a second color, for example, light in a green wavelength band. The green wavelength band may be in a range of about 480 nm to about 560 nm. Therefore, the second color filter CF2 may transmit light of a second color among light emitted from the second light emitting area EA2.

The third color filter CF3 may overlap the third light emitting area EA3 of the third sub-pixel SP3. The third color filter CF3 may transmit light of a third color, for example, light in a red wavelength band. The red wavelength band may be in a range of about 600 nm to about 750 nm. Therefore, the third color filter CF3 may transmit light of a third color among light emitted from the third light emitting area EA3.

Each of the lenses LNS may be disposed on each of the first color filter CF1, the second color filter CF2, and the third color filter CF3. Each of the lenses LNS may be a structure for increasing a ratio of light directed to the front of the display device 10. Each of the lenses LNS may have a cross-sectional shape that is convex in an upward direction.

The filling layer FIL may be disposed on the lenses LNS. The filling layer FIL may have a selectable refractive index so that light travels in the third direction DR3 at an interface between the lenses LNS and the filling layer FIL. The filling layer FIL may be a planarization layer. The filling layer FIL may be an organic film made of an acryl resin, an epoxy resin, a phenolic resin, a polyamide resin, or a polyimide resin.

The cover layer CVL may be disposed on the filling layer FIL. The cover layer CVL may be a glass substrate or a polymer resin such as resin. In case that the cover layer CVL is a glass substrate, the cover layer CVL may be attached onto the filling layer FIL. In this case, the filling layer FIL may serve to adhere the cover layer CVL. In case that the cover layer CVL is a glass substrate, the cover layer CVL may serve as an encapsulation substrate. In case that the cover layer CVL is a polymer resin such as resin, the cover layer CVL may be directly applied on the filling layer FIL.

The polarizing plate (not illustrated) may be disposed on one surface or a surface of the cover layer CVL. The polarizing plate may be a structure for preventing deterioration in visibility due to reflection of external light. The polarizing plate may include a linear polarizing plate and a phase retardation film. For example, the phase retardation film may be a λ/4 (quarter-wave) plate, but the specification is not limited thereto. However, in case that deterioration in visibility due to reflection of external light is sufficiently improved by the first to third color filters CF1, CF2, and CF3, the polarizing plate may also be omitted.

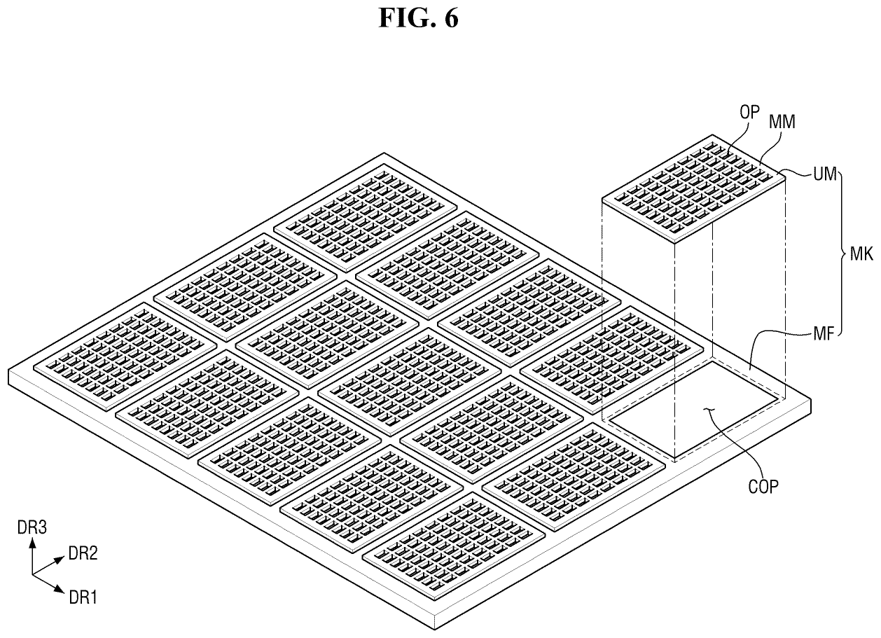

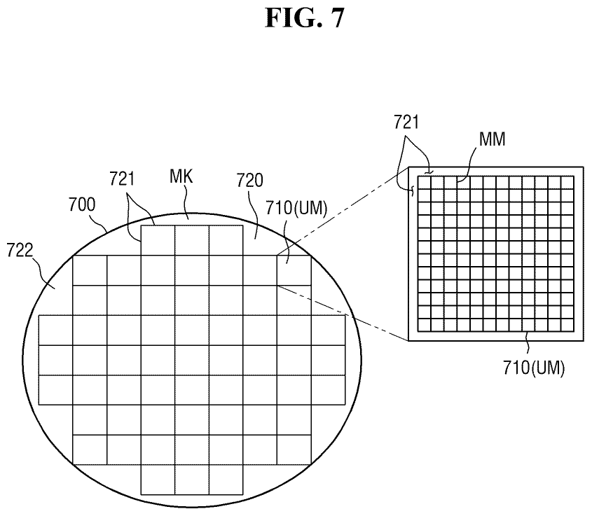

FIG. 6 is a schematic perspective view of a mask according to an embodiment. FIG. 7 is a schematic plan view of the mask according to an embodiment. FIG. 6 illustrates a schematic perspective view of a state in which one unit mask UM is separated from unit masks. The mask according to an embodiment illustrated in FIGS. 6 and 7 may be used in a process of depositing at least a portion of the intermediate layer IL of the display panel 410 described with reference to FIG. 5. For example, the intermediate layer IL may emit different colors from each of the sub-pixels SP1, SP2, and SP3.

Referring to FIGS. 6 and 7, the mask MK according to an embodiment may be a shadow mask in which a mask membrane MM is disposed on a silicon substrate 700. The mask MK according to an embodiment may be named “silicon mask.”

According to an embodiment, the mask MK may include a silicon substrate 700, and a mask rib 7211 and a mask membrane MM may be disposed on the silicon substrate 700.

The silicon substrate 700 may include cell areas 710 corresponding to the unit masks UM and a mask frame area 720. The mask frame area 720 may be the remaining area excluding the cell areas 710. The mask frame area 720 may include a mask rip area 721 that partitions the cell areas 710 and an outer frame area 722 positioned on an outer portion of the silicon substrate 700.

A mask frame MF is disposed in the mask frame area 720. The mask frame MF may be formed of silicon, which is a portion of the silicon substrate 700. The mask frame MF may be formed of a metal, for example, a plating film formed on the silicon substrate 700. The mask frame MF may include a stacked structure including silicon, which is a portion of the silicon substrate 700, and a metal, for example, a plating film, formed on the silicon.

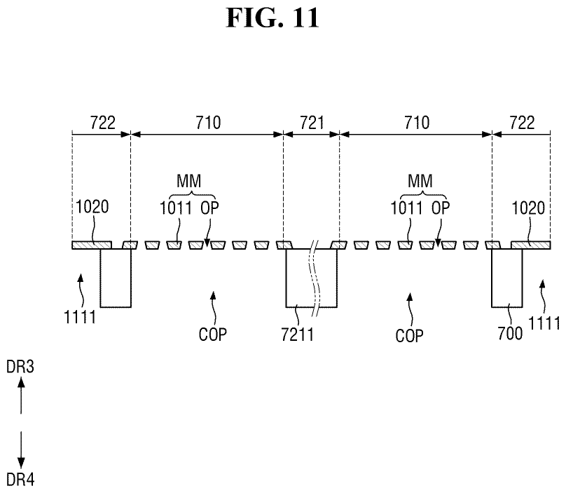

The mask rip area 721 of the mask frame area 720 may be an area that partitions the cell areas 710. For example, the cell areas 710 may be disposed in a matrix form, and the mask rip area 721 may be disposed to surround each cell area 710. A mask rip (7211 in FIG. 11) is disposed in such a mask rip area 721. According to an embodiment, by forming the mask rip 7211 from a magnetic metal material, sagging of the mask MK may be prevented using a magnetic member (for example, magnetic chuck) inside the deposition device (not illustrated). However, the disclosure is not limited to forming the mask rip 7211 from the magnetic metal material, and the mask rip 7211 may be formed of the silicon substrate 700. The mask rip 7211 may be formed of the silicon substrate 700 and a metal disposed on the silicon substrate 700. The mask rip 7211 may be formed of the silicon substrate 700 and an inorganic film disposed on the silicon substrate 700.

A cell opening COP and a unit mask UM masking at least a portion of the cell opening COP may be disposed in each of the cell areas 710 of the silicon substrate 700.

Cell openings COP may penetrate through the mask frame MF along a thickness direction (for example, third direction DR3) of the mask MK. The cell openings COP may be generated by etching a portion of the silicon substrate 700 from a rear direction DR4.

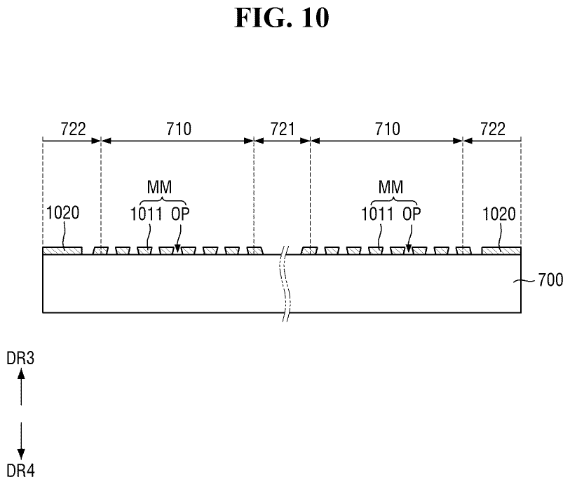

Each unit mask UM may include a mask membrane MM, and the mask membrane MM may include mask shadows (1011 in FIG. 10) masking at least a portion of the cell opening COP, and a mask opening (OP in FIG. 10) disposed between the mask shadows 1011 adjacent to each other. The mask shadows 1011 may be disposed in a matrix form within each unit mask UM, and the mask opening OP may be disposed between the mask shadows 1011.

In case that a deposition material evaporates from a deposition source inside the deposition device, the mask shadows 1011 may serve as blocking portions that mask a substrate to be deposited (for example, the display panel 410 or the backplane substrate). Accordingly, the deposition material generated from the deposition source DS may be deposited on a surface of the substrate to be deposited (for example, the display panel 410 or the backplane substrate) through the mask opening OP of the mask membrane MM.

The mask opening OP of the mask membrane MM may be named “hole” or “mask hole”. The mask openings OP may penetrate through the unit masks UM along the thickness direction (for example, third direction DR3) of the mask MK.

One unit mask UM may be used in a deposition process of one display panel 410. In the disclosure, the term “unit mask UM” may be replaced with terms such as a mask unit UM or a unit mask UM.

The outer frame area 722 of the mask frame area 720 is an area that supports the entire mask MK and may be disposed to surround the outer portion of the mask MK. A first metal frame (1020 in FIG. 10) connected to the mask membrane MM disposed in the cell opening COP is disposed in at least a portion of the outer frame area 722.

The first metal frame 1020 is formed of a metal material and is disposed to surround the outer portion of the mask MK. For example, the silicon substrate 700 may have a circular shape in plan view, and the first metal frame 1020 may have a ring shape surrounding an outer portion of the silicon substrate 700 in plan view.

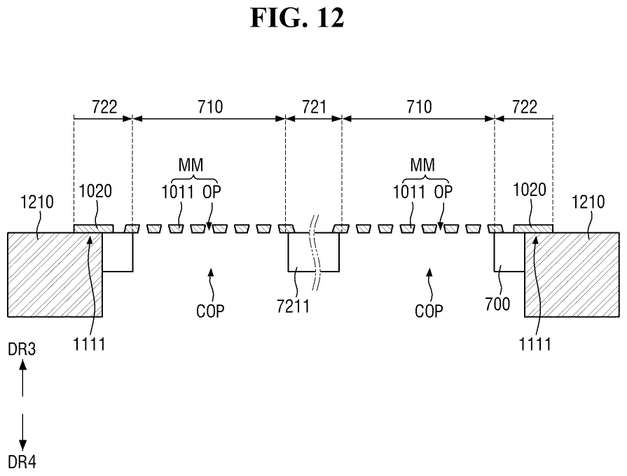

The first metal frame 1020 is coupled to a second metal frame (1210 in FIG. 12) that is provided separately from the silicon substrate 700. The second metal frame 1210 may have a ring shape surrounding the outer portion of the silicon substrate 700 in plan view. The second metal frame 1210 is coupled to the first metal frame 1020 disposed on the outer portion of the silicon substrate 700. For example, the first metal frame 1020 may be disposed in the outer frame area 722, which is the outer portion of the silicon substrate 700, and a lower surface of the first metal frame 1020 may be exposed as the silicon substrate 700 is etched. The lower surface of the first metal frame 1020 exposed by etching the silicon substrate 700 may be coupled to an upper surface of the second metal frame 1210. Examples of a method of coupling the first metal frame 1020 and the second metal frame 1210 include welding, but the disclosure is not limited thereto. For example, the examples of a method of coupling the first metal frame 1020 and the second metal frame 1210 may include coupling by adhesive or screwing in addition to welding.

In the disclosure, the lower surface or rear surface refers to a surface facing a rear direction of the silicon substrate, and the rear direction refers to a direction from the mask MK toward the deposition source.

The second metal frame 1210 may have substantially the same size as the silicon substrate 700. For example, the second metal frame 1210 may have a ring shape surrounding the silicon substrate 700, and a diameter of the second metal frame 1210 may be substantially the same as a diameter of the silicon substrate 700. However, the diameter of the second metal frame 1210 may also be designed to be greater than the diameter of the silicon substrate 700.

According to an embodiment, the mask MK may be readily implemented for manufacturing the high-resolution display panel 410 by forming the shadow mask (for example, mask membrane MM) on the silicon substrate 700. The mask MK may be attached to the substrate to be deposited without a separate structure inside the deposition device by disposing the first metal frame 1020 on the outer portion of the silicon substrate 700 and coupling the first metal frame 1020 to the second metal frame 1210 that is provided separately from the silicon substrate 700. The mask MK according to an embodiment may prevent mura defects as sagging of the mask MK is reduced by the coupling of the first metal frame 1020 and the second metal frame 1210.

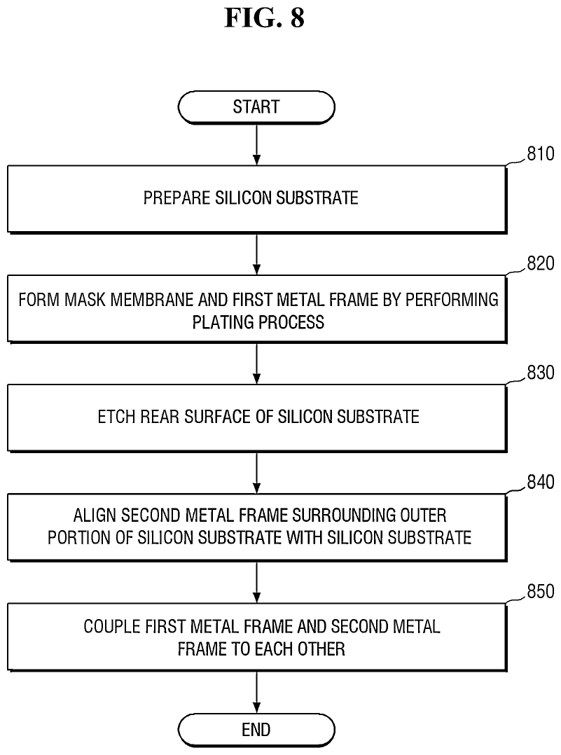

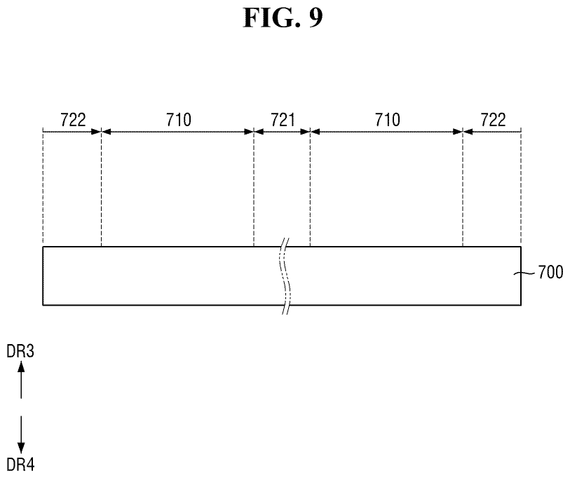

FIG. 8 is a flowchart illustrating a method for manufacturing a mask according to an embodiment. FIGS. 9 to 13 are schematic cross-sectional process views for describing a method for manufacturing a mask according to an embodiment.

Hereinafter, a method for manufacturing the mask MK according to an embodiment will be described with reference to FIGS. 8 to 13. The following description is only a portion of the processes of manufacturing the mask MK, and additional processes for forming the components described with reference to the disclosure may be performed before or after each step. A process of manufacturing the mask MK may be additionally performed before or after each step described below.

Referring to FIGS. 8 and 9, in step 810, a silicon substrate 700 is prepared. The silicon substrate 700 may include cell areas 710 corresponding to the unit masks UM and a mask frame area 720. The mask frame area 720 may be the remaining area excluding the cell areas 710. The mask frame area 720 may include a mask rip area 721 that partitions the cell areas 710 and an outer frame area 722 positioned on an outer portion of the silicon substrate 700.

Referring to FIGS. 8 and 10, in step 820, a mask membrane MM and a first metal frame 1020 are formed by performing a plating process. The plating process may include forming a photoresist pattern for forming the mask membrane MM on the silicon substrate 700, growing a plating film on the silicon substrate 700 including the photoresist pattern, and removing the photoresist pattern.

An area from which the photoresist pattern is removed from each cell area of the silicon substrate 700 becomes a mask opening OP of the mask membrane MM. The plating film may include tungsten (W) or copper (Cu). In each cell area of the silicon substrate 700, a mask shadow 1011 of the mask membrane MM is formed by the plating film.

A first metal frame 1020 connected to the mask membrane MM is formed on at least a portion of an outer frame area 722 of the silicon substrate 700 using the plating film. The mask shadow 1011 of the mask membrane MM and the first metal frame 1020 may be formed through the same plating process.

A cross section of the mask membrane (MM) (for example, a cross section of each mask shadow 1011) may have a reverse taper shape whose width becomes narrower from a front direction DR3 of the silicon substrate 700 to a rear direction DR4 of the silicon substrate 700. A cross section of the mask opening OP may have a regular taper shape whose width increases from the front direction DR3 of the silicon substrate 700 to the rear direction DR4 of the silicon substrate 700. According to an embodiment of the disclosure, shadow defects during the deposition process may be reduced by having the cross section of the mask membrane MM have the reverse taper shape.

A thickness of the mask membrane MM (for example, a thickness of each mask shadow 1011) may be less than about 2 μm. In case that the thickness of the mask membrane MM is less than about 2 μm, there may be a problem in which the mask membrane MM is readily rolled, but this problem may be prevented by having a portion of the silicon substrate 700 positioned between the cell areas 710 adjacent to each other serve as a mask rip 7211. In the mask MK according to an embodiment, the thickness of the mask membrane MM is less than about 2 μm, thereby reducing shadow defects and preventing sagging of the mask MK.

Referring to FIGS. 8 and 11, in step 830, a rear surface of the silicon substrate 700 is etched. For example, a process of etching the rear surface of the silicon substrate 700 may include forming a photoresist pattern on the rear surface of the silicon substrate 700, etching a portion of the silicon substrate 700 from the rear direction DR4 using the photoresist pattern, and removing the photoresist pattern. Accordingly, a cell opening COP corresponding to the cell area 710 and a frame opening 1111 exposing a lower surface of the first metal frame 1020 in the outer frame area 722 are formed on the rear surface of the silicon substrate 700. A portion of the first metal frame 1020 may be supported by a portion of the silicon substrate 700 disposed in the outer frame area 722, and the lower surface of the remaining area except for a portion of the first metal frame 1020 may be exposed during the process through the frame opening 1111.

According to an embodiment, in the process of etching the rear surface of the silicon substrate 700, a portion of the silicon substrate 700 corresponding to the mask rip area 721 is masked. Therefore, the mask rips 7211 positioned between the cell areas 710 adjacent to each other may be formed by a portion of the silicon substrate 700 masked in the etching process.

Referring to FIGS. 8 and 12, in step 840, a second metal frame 1210 that surrounds an outer portion of the silicon substrate 700 is aligned with the silicon substrate 700. The second metal frame 1210 may have a ring shape surrounding the outer portion of the silicon substrate 700 in plan view. The second metal frame 1210 is aligned with the outer frame area 722 of the silicon substrate 700. For example, the second metal frame 1210 may be aligned to overlap a frame opening 1111 of the silicon substrate 700 that exposes the lower surface of the first metal frame 1020. A thickness of the second metal frame 1210 may be thicker than a thickness of the silicon substrate 700.

The second metal frame 1210 may be made of a rigid material. For example, the material of the second metal frame 1210 may include stainless steel, invar, nickel (Ni), cobalt (Co), a nickel alloy, and/or a nickel-cobalt alloy.

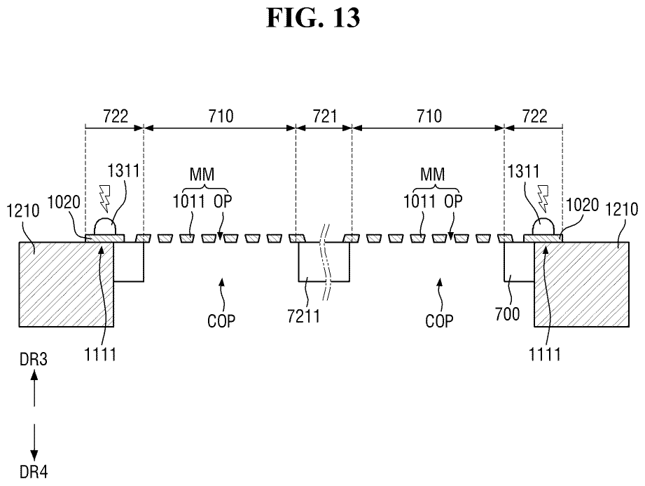

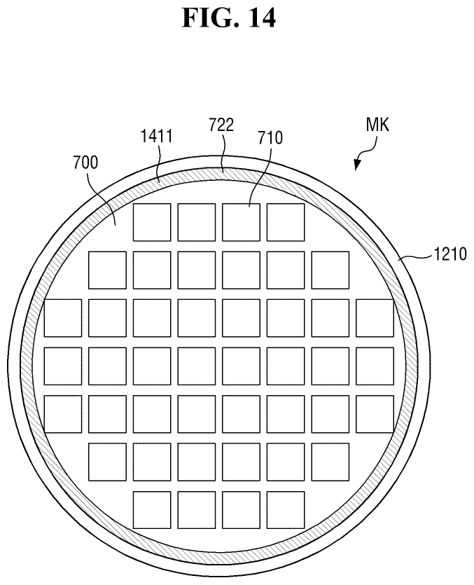

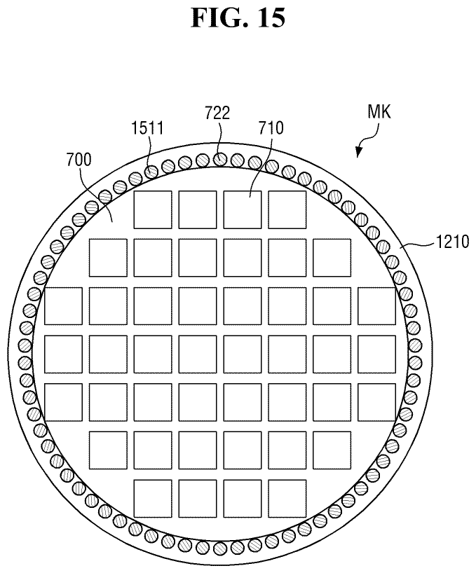

Referring to FIGS. 8 and 13, in step 850, the first metal frame 1020 and the second metal frame 1210 are coupled to each other. As illustrated at 1311 in FIG. 13, the process of coupling the first metal frame 1020 and the second metal frame 1210 to each other may include welding. In the disclosure, an area where the first metal frame 1020 and the second metal frame 1210 are welded is defined as a “welded portion.” According to an embodiment, the welded portion may be disposed in the outer frame area 722 of the silicon substrate 700 and may be disposed along a perimeter of the second metal frame 1210. The given position of the welded portion will be described later with reference to FIGS. 14 and 15.

In the embodiment of FIGS. 8 to 13, the process (step 850) of coupling the first metal frame 1020 and the second metal frame 1210 to each other was performed after the process (step 830) of etching the rear surface of the silicon substrate 700, but the disclosure is not limited thereto. For example, the process (step 850) of coupling the first metal frame 1020 and the second metal frame 1210 to each other may also be performed before the process (step 830) of etching the rear surface of the silicon substrate 700.

FIG. 14 is a schematic plan view of a mask for describing a position of a welded portion between the silicon substrate 700 and the second metal frame 1210 according to an embodiment.

Referring to FIG. 14, the welded portion 1411 of the silicon substrate 700 and the second metal frame 1210 may be disposed to continuously extend along the perimeter of the second metal frame 1210. For example, the welded portion 1411 is disposed along an overlapping portion of the outer frame area 722 of the silicon substrate 700 and the second metal frame 1210. The welded portion 1411 may be disposed to continuously extend in a ring shape in case that the mask MK is viewed in plan view.

FIG. 15 is a schematic plan view of a mask in which a position of a welded portion between the silicon substrate 700 and the second metal frame 1210 is changed according to an embodiment.

Referring to FIG. 15, welded portions 1511 of the silicon substrate 700 and the second metal frame 1210 may be discontinuously disposed along the perimeter of the second metal frame 1210. For example, the welded portions 1511 are disposed along the overlapping portion of the outer frame area 722 of the silicon substrate 700 and the second metal frame 1210 and may be disposed to be spaced apart at a designated interval. In the specification, the interval between the welded portions 1511 adjacent to each other is not limited.

In the embodiment of FIG. 15, unlike the embodiment of FIG. 14, stress applied to the silicon substrate 700 may be reduced by setting the welded portions 1511 discontinuously. For example, in case that the welded portions 1511 are designed in the form of a discontinuous dot as in the embodiment of FIG. 15, sagging or distortion of the silicon substrate due to the stress applied to the silicon substrate 700 may be reduced.

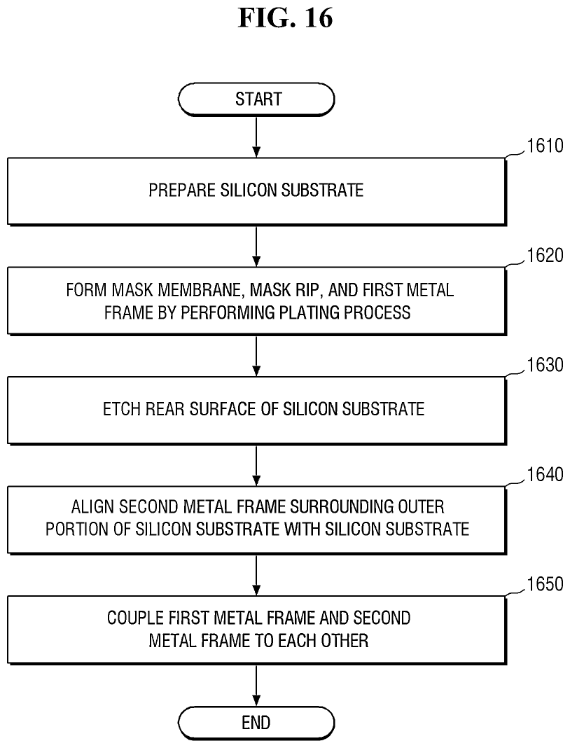

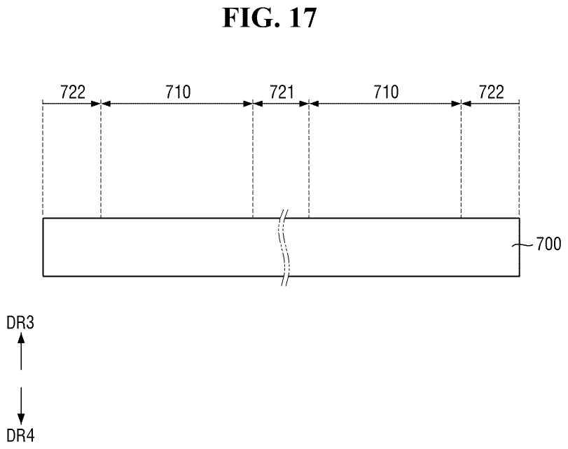

FIG. 16 is a flowchart illustrating a method for manufacturing a mask according to an embodiment. FIGS. 17 to 21 are schematic cross-sectional process views for describing a method for manufacturing a mask according to an embodiment.

The embodiment of FIGS. 16 to 21 may be different from the embodiment of FIGS. 8 to 13 in that the mask rips 7211 positioned between the cell areas 710 adjacent to each other may be formed of a plating film.

Hereinafter, a method for manufacturing the mask MK according to an embodiment will be described with reference to FIGS. 16 to 21. The following description is only a portion of the processes of manufacturing the mask MK, and additional processes for forming the components described with reference to the disclosure may be performed before or after each step. A process of manufacturing the mask MK may be additionally performed before or after each step described below.

Referring to FIGS. 16 and 17, in step 1610, a silicon substrate 700 is prepared. The silicon substrate 700 may include cell areas 710 corresponding to the unit masks UM and a mask frame area 720. The mask frame area 720 may be the remaining area excluding the cell areas 710. The mask frame area 720 may include a mask rip area 721 that partitions the cell areas 710 and an outer frame area 722 positioned on an outer portion of the silicon substrate 700.

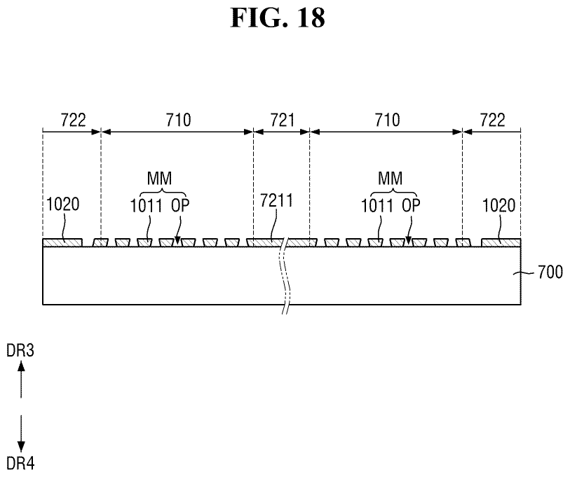

Referring to FIGS. 16 and 18, in step 1620, a mask membrane MM, a mask rip 7211, and a first metal frame 1020 are formed by performing a plating process. The plating process may include forming a photoresist pattern for forming the mask membrane MM on the silicon substrate 700, growing a plating film on the silicon substrate 700 including the photoresist pattern, and removing the photoresist pattern.

An area from which the photoresist pattern is removed from each cell area of the silicon substrate 700 becomes a mask opening OP of the mask membrane MM. The plating film may include tungsten (W) or copper (Cu). In each cell area of the silicon substrate 700, a mask shadow 1011 of the mask membrane MM is formed by the plating film.

A mask rip 7211 formed of a plating film is disposed in a mask rip area 721 of the silicon substrate 700. According to an embodiment, by forming the mask rip 7211 from a magnetic metal material, sagging of the mask MK may be prevented using a magnetic member (for example, magnetic chuck) inside the deposition device (not illustrated).

A first metal frame 1020 connected to the mask membrane MM is formed on at least a portion of an outer frame area 722 of the silicon substrate 700 using the plating film. The mask shadow 1011 of the mask membrane MM and the first metal frame 1020 may be formed through the same plating process.

A thickness of the mask membrane MM (for example, a thickness of each mask shadow 1011) and a thickness of the mask rip 7211 may be about 2 μm or more. For example, in the embodiment of FIG. 18, unlike the embodiment of FIG. 10, the thickness of the plating film may be formed to be about 2 μm or more. In the embodiment of FIG. 18, by forming the mask membrane MM and the mask rip 7211 from the plating film having the thickness of about 2 μm or more, magnetic force may be increased, and thus the effect of preventing sagging of the mask MK can be increased by using the magnetic member (for example, magnetic chuck).

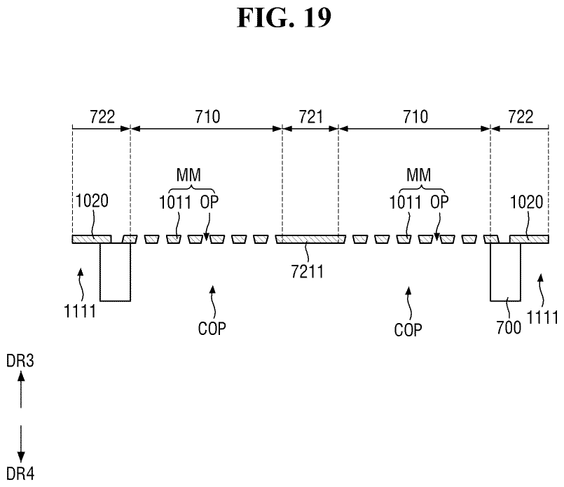

Referring to FIGS. 16 and 19, in step 1630, a rear surface of the silicon substrate 700 is etched. For example, a process of etching the rear surface of the silicon substrate 700 may include forming a photoresist pattern on the rear surface of the silicon substrate 700, etching a portion of the silicon substrate 700 from the rear direction DR4 using the photoresist pattern, and removing the photoresist pattern. Accordingly, a cell opening COP corresponding to the cell area 710 and a frame opening 1111 exposing a lower surface of the first metal frame 1020 in the outer frame area 722 are formed on the rear surface of the silicon substrate 700. A portion of the first metal frame 1020 may be supported by a portion of the silicon substrate 700 disposed in the outer frame area 722, and the lower surface of the remaining area except for a portion of the first metal frame 1020 may be exposed during the process through the frame opening 1111.

In step 1630, unlike step 830, a portion of the silicon substrate 700 corresponding to the mask rip area 721 is also etched. Accordingly, only the mask rip 7211 formed by the plating film is left in the mask rip area 721.

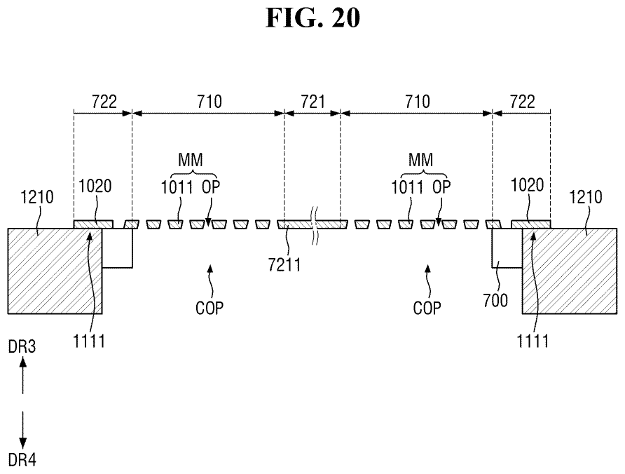

Referring to FIGS. 16 and 20, in step 1640, a second metal frame 1210 that surrounds an outer portion of the silicon substrate 700 is aligned with the silicon substrate 700. The second metal frame 1210 may have a ring shape surrounding the outer portion of the silicon substrate 700 in plan view. The second metal frame 1210 is aligned with the outer frame area 722 of the silicon substrate 700. For example, the second metal frame 1210 may be aligned to overlap a frame opening 1111 of the silicon substrate 700 that exposes the lower surface of the first metal frame 1020. A thickness of the second metal frame 1210 may be thicker than a thickness of the silicon substrate 700.

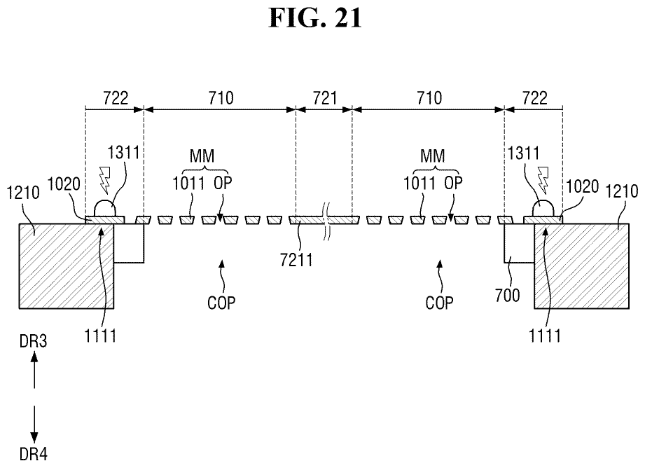

Referring to FIGS. 16 and 21, in step 1650, the first metal frame 1020 and the second metal frame 1210 are coupled to each other. As illustrated at 1311 in FIG. 21, the process of coupling the first metal frame 1020 and the second metal frame 1210 to each other may include welding.

In the embodiment of FIGS. 16 to 21, the process (step 1650) of coupling the first metal frame 1020 and the second metal frame 1210 to each other was performed after the process (step 1630) of etching the rear surface of the silicon substrate 700, but the disclosure is not limited thereto. For example, the process (step 1650) of coupling the first metal frame 1020 and the second metal frame 1210 to each other may also be performed before the process (step 1630) of etching the rear surface of the silicon substrate 700.

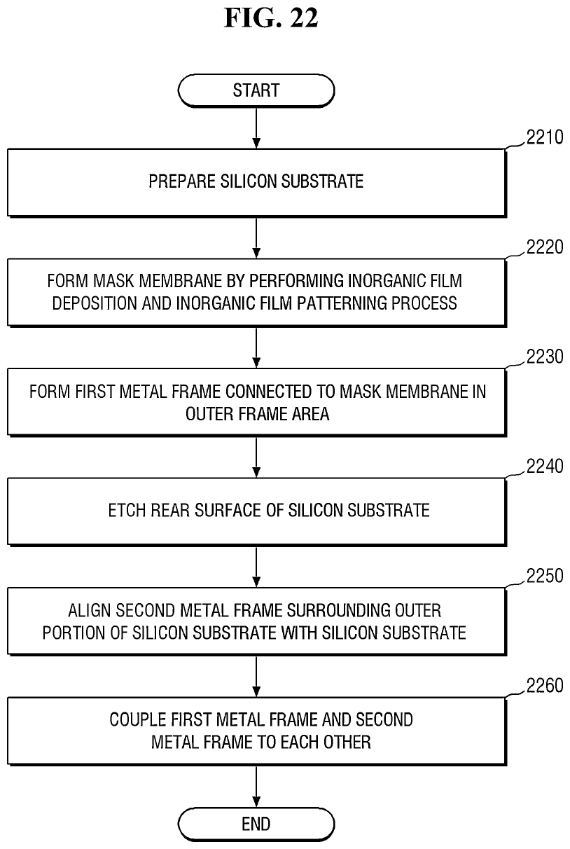

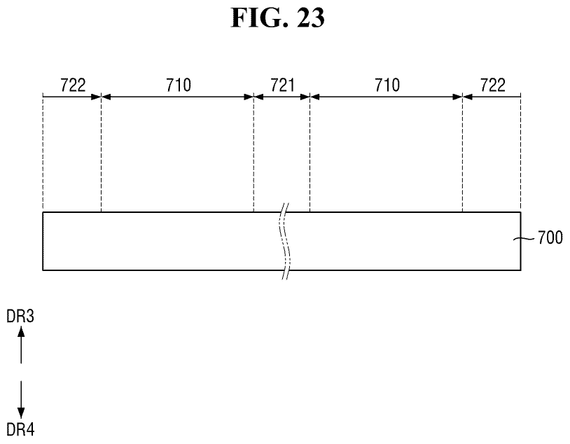

FIG. 22 is a flowchart illustrating a method for manufacturing a mask according to an embodiment. FIGS. 23 to 27 are schematic cross-sectional process views for describing a method for manufacturing a mask according to an embodiment.

The embodiment of FIGS. 22 to 27 may be different from the embodiment of FIGS. 8 to 13 in that the mask shadow 1011 of the mask membrane MM may be formed of an inorganic film pattern.

Hereinafter, a method for manufacturing the mask MK according to an embodiment will be described with reference to FIGS. 22 to 27. The following description is only a portion of the processes of manufacturing the mask MK, and additional processes for forming the components described with reference to the disclosure may be performed before or after each step. A process of manufacturing the mask MK may be additionally performed before or after each step described below.

Referring to FIGS. 22 and 23, in step 2210, a silicon substrate 700 is prepared. The silicon substrate 700 may include cell areas 710 corresponding to the unit masks UM and a mask frame area 720. The mask frame area 720 may be the remaining area excluding the cell areas 710. The mask frame area 720 may include a mask rip area 721 that partitions the cell areas 710 and an outer frame area 722 positioned on an outer portion of the silicon substrate 700.

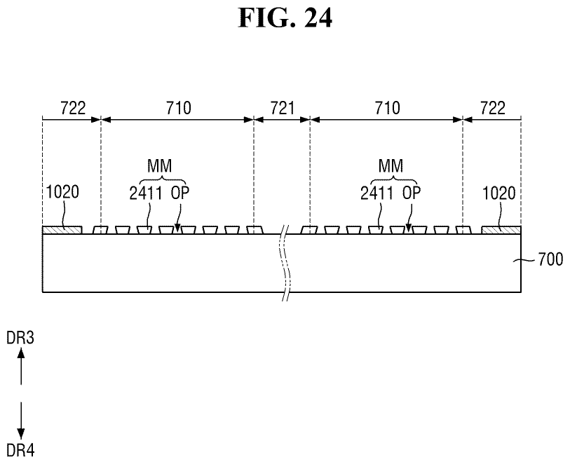

Referring to FIGS. 22 and 24, in step 2220, a mask membrane MM is formed by performing an inorganic film deposition and inorganic film patterning process. The process of forming the mask membrane MM may include depositing an inorganic film on the silicon substrate 700, forming a photoresist pattern on the inorganic film, patterning a portion of the inorganic film using the photoresist pattern, and removing the photoresist pattern.

The inorganic film may include a silicon-based material. For example, the inorganic film pattern may include at least one material of silicon (Si), silicon nitride (SiNₓ), silicon oxynitride (SiON), silicon oxide (SiOₓ), titanium oxide (TiOₓ), amorphous silicon (a-Si), and aluminum oxide layer (AlOₓ).

The mask membrane MM disposed in each cell area 710 may include a mask shadow 2411 and a mask opening OP formed in an inorganic film pattern.

Referring to FIGS. 22 and 24, in step 2230, a first metal frame 1020 connected to the mask membrane MM is formed in the outer frame area 722 of the silicon substrate 700.

The first metal frame 1020 may be formed of a plating film. The plating film may include tungsten (W) or copper (Cu).

The first metal frame 1020 may be made of a rigid material. For example, the material of the first metal frame 1020 may include titanium nitride (TiN), stainless steel, invar, nickel (Ni), cobalt (Co), a nickel alloy, and/or a nickel-cobalt alloy.

The process of forming the first metal frame 1020 may be the same process as a process of forming an alignment key of the mask MK. For example, an alignment key is disposed in a portion of the outer frame area 722 of the silicon substrate 700, and the first metal frame 1020 and the alignment key may be formed of the same material in the same process.

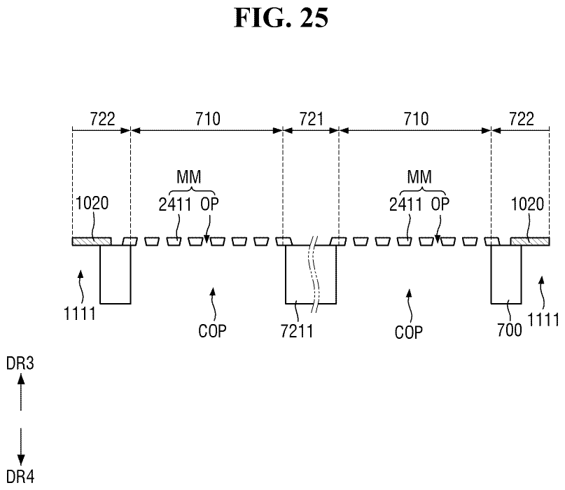

Referring to FIGS. 22 and 25, in step 2240, a rear surface of the silicon substrate 700 is etched. For example, a process of etching the rear surface of the silicon substrate 700 may include forming a photoresist pattern on the rear surface of the silicon substrate 700, etching a portion of the silicon substrate 700 from the rear direction DR4 using the photoresist pattern, and removing the photoresist pattern. Accordingly, a cell opening COP corresponding to the cell area 710 and a frame opening 1111 exposing a lower surface of the first metal frame 1020 in the outer frame area 722 are formed on the rear surface of the silicon substrate 700. A portion of the first metal frame 1020 may be supported by a portion of the silicon substrate 700 disposed in the outer frame area 722, and the lower surface of the remaining area except for a portion of the first metal frame 1020 may be exposed during the process through the frame opening 1111.

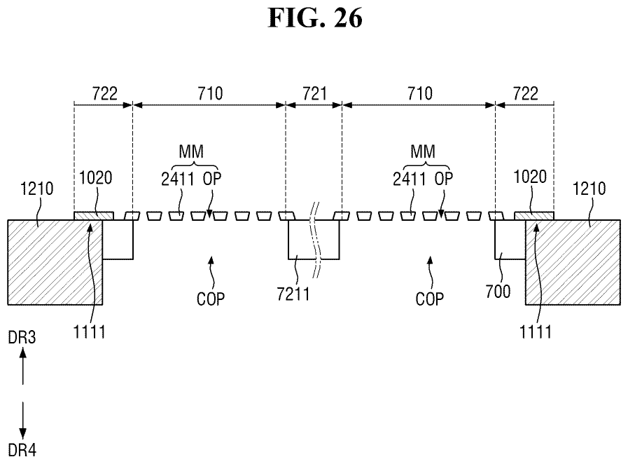

Referring to FIGS. 22 and 26, in step 2250, a second metal frame 1210 that surrounds an outer portion of the silicon substrate 700 is aligned with the silicon substrate 700. The second metal frame 1210 may have a ring shape surrounding the outer portion of the silicon substrate 700 in plan view. The second metal frame 1210 is aligned with the outer frame area 722 of the silicon substrate 700. For example, the second metal frame 1210 may be aligned to overlap a frame opening 1111 of the silicon substrate 700 that exposes the lower surface of the first metal frame 1020. A thickness of the second metal frame 1210 may be thicker than a thickness of the silicon substrate 700.

The second metal frame 1210 may be made of a rigid material. For example, the material of the second metal frame 1210 may include stainless steel, invar, nickel (Ni), cobalt (Co), a nickel alloy, and/or a nickel-cobalt alloy.

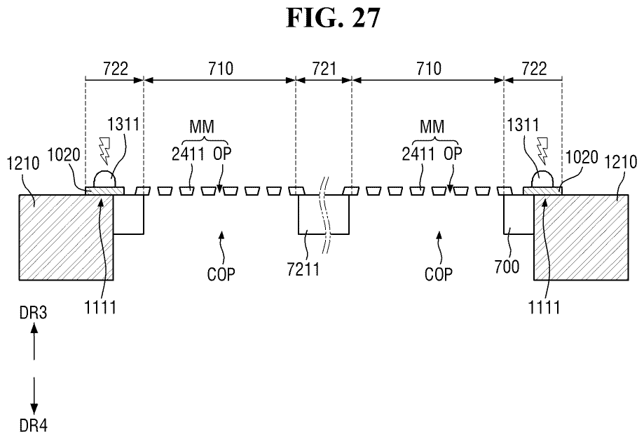

Referring to FIGS. 22 and 27, in step 2260, the first metal frame 1020 and the second metal frame 1210 are coupled to each other. As illustrated at 1311 in FIG. 27, the process of coupling the first metal frame 1020 and the second metal frame 1210 to each other may include welding.

In the embodiment of FIGS. 22 to 27, the process (step 2260) of coupling the first metal frame 1020 and the second metal frame 1210 to each other was performed after the process (step 2240) of etching the rear surface of the silicon substrate 700, but the disclosure is not limited thereto. For example, the process (step 2260) of coupling the first metal frame 1020 and the second metal frame 1210 to each other may also be performed before the process (step 2240) of etching the rear surface of the silicon substrate 700.

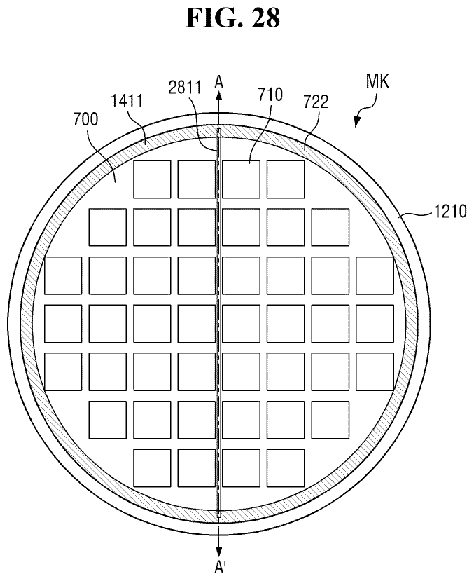

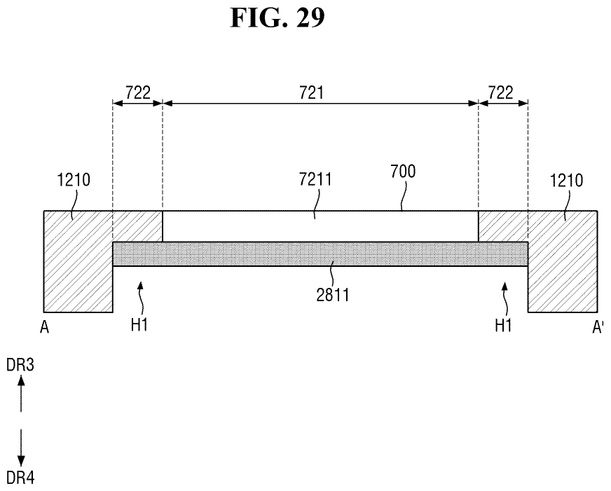

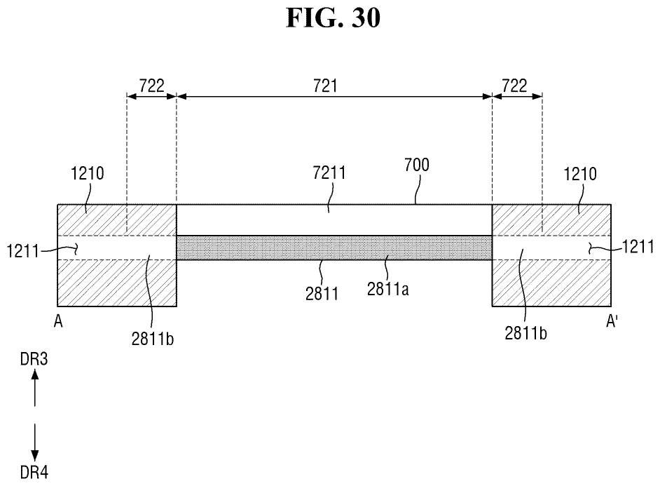

FIG. 28 is a schematic plan view of a mask including a metal sheet 2811 according to an embodiment. FIGS. 29 and 30 are schematic cross-sectional views of a mask in which the metal sheet 2811 is coupled to a lower surface of the silicon substrate 700 according to an embodiment. For example, FIGS. 29 to 30 are schematic cross-sectional views of the mask taken along line A-A′ illustrated in FIG. 28.

Referring to FIGS. 28 to 30, the mask MK according to an embodiment may further include a metal sheet 2811 that supports the mask MK in the rear direction DR4. The metal sheet 2811 may be disposed to cross the mask MK in a horizontal direction, or may be disposed to cross the mask MK in a vertical direction in plan view. It is illustrated in FIG. 28 that the metal sheet 2811 crosses the mask MK in the vertical direction, but the disclosure is not limited thereto.

The metal sheet 2811 may be made of a rigid material. For example, the material of the metal sheet 2811 may include invar, but is not limited thereto. The material of the metal sheet 2811 may include stainless steel, nickel (Ni), cobalt (Co), a nickel alloy, and/or a nickel-cobalt alloy.

Both ends of the metal sheet 2811 are fixed by being coupled to the second metal frame 1210 in the outer frame area 722 of the silicon substrate 700.

According to an embodiment, as illustrated in FIG. 29, a lower step portion Hl on which the metal sheet 2811 is seated may be formed on the rear of the second metal frame 1210 corresponding to the outer frame area 722 of the silicon substrate 700. The metal sheet 2811 may be coupled to the lower step portion H1 of the second metal frame 1210 by an adhesive or welding process.

According to an embodiment, as illustrated in FIG. 30, the second metal frame 1210 may not have the lower step portion H1, but may instead include a groove 1211 into which the metal sheet 2811 is inserted. A side surface of the second metal frame 1210 may include the groove 1211 into which the metal sheet 2811 is inserted, and a height of the groove 1211 may be designed to be substantially the same as a height of the metal sheet 2811. Both ends of the metal sheet 2811 are inserted into the grooves 1211 formed on the side surface of the second metal frame 1210, and the remainder supports the mask rip 7211. For example, the metal sheet 2811 may include a first portion 2811a supporting the mask rip 7211 in the mask rip area 721 of the silicon substrate 700, and a second portion 2811b positioned at each end of the first portion 2811a and inserted into the groove 1211 of the second metal frame 1210.

The metal sheet 2811 is disposed to extend from one side or a side of the silicon substrate 700 to the other side of the silicon substrate 700 along the mask rip area 721 of the silicon substrate 700.

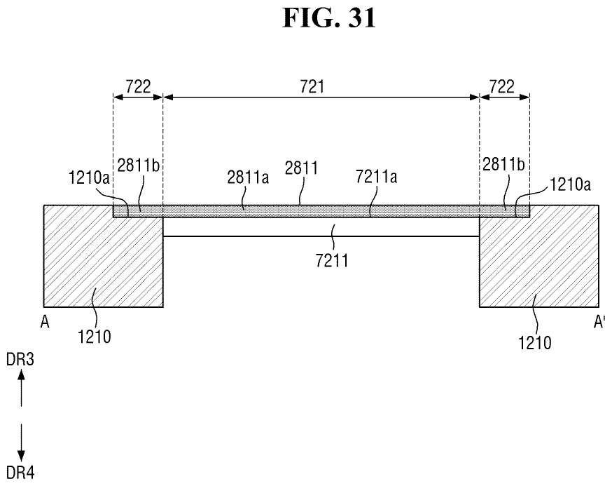

FIG. 31 is a schematic cross-sectional view of a mask in which the metal sheet 2811 is coupled to an upper surface of the silicon substrate 700 according to an embodiment. For example, FIG. 31 is a schematic cross-sectional view of the mask taken along line A-A′ illustrated in FIG. 28.

The embodiment of FIG. 31 may be different from the embodiment of FIGS. 29 and 30 in that the metal sheet 2811 may be coupled to an upper surface of the second metal frame 1210 and an upper surface 7211a of the mask rip 7211.

Referring to FIG. 31, the mask MK according to an embodiment may include a metal sheet 2811 coupled to an upper surface of the second metal frame 1210. An upper step portion 1210a on which the metal sheet 2811 is seated may be formed on the upper surface of the second metal frame 1210 corresponding to the outer frame area 722 of the silicon substrate 700. The metal sheet 2811 may be coupled to the upper step portion 1210a of the second metal frame 1210 by an adhesive or welding process.

The metal sheet 2811 may include a first portion 2811a disposed to overlap the mask rip 7211 in the mask rip area 721 of the silicon substrate 700, and a second portion 2811b positioned at each end of the first portion 2811a and coupled to the upper step portion 1210a of the second metal frame 1210.

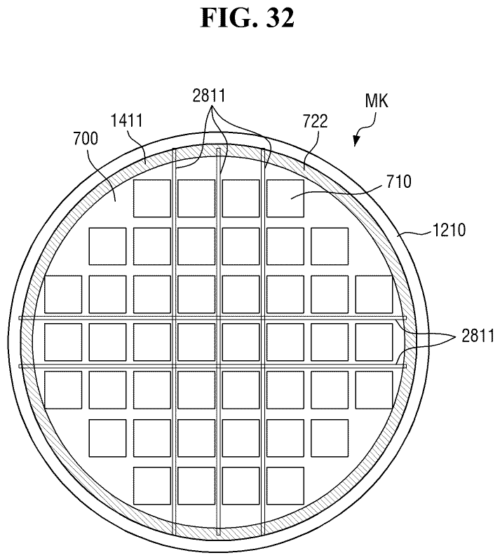

FIG. 32 is a schematic plan view of a mask including metal sheets 2811 according to an embodiment.

The embodiment of FIG. 32 may be different from the embodiment of FIGS. 28 to 31 in that the mask may be coupled to metal sheets 2811.

Referring to FIG. 32, the mask MK according to an embodiment is coupled to metal sheets 2811. The metal sheets 2811 may be disposed to cross the mask MK in a horizontal direction, or may be disposed to cross the mask MK in a vertical direction in plan view.

It is illustrated in FIG. 32 that two metal sheets 2811 are disposed to cross the mask MK in the horizontal direction and three metal sheets 2811 are disposed to cross the mask MK in the vertical direction, but the disclosure is not limited thereto. The metal sheets 2811 illustrated in FIG. 32 may be coupled to the second metal frame 1210 in the same or similar manner as the metal sheets 2811 described with reference to FIGS. 28 to 31.

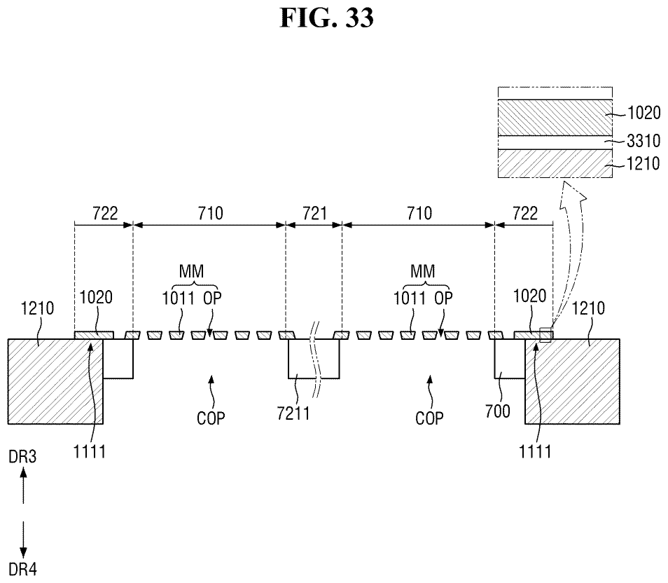

FIG. 33 is a conceptual view for describing a coupling of a first metal frame 1020 and a second metal frame 1210 using an adhesive.

The embodiment of FIG. 33 may be different from the embodiment of FIG. 13 in that the first metal frame 1020 and the second metal frame 1210 may be coupled using an adhesive 3310.

Referring to FIG. 33, in the mask MK according to an embodiment, the first metal frame 1020 may be disposed in the outer frame area 722 of the silicon substrate, and the first metal frame 1020 may be coupled to the second metal frame 1210, which is provided separately from the silicon substrate 700, using the adhesive 3310.

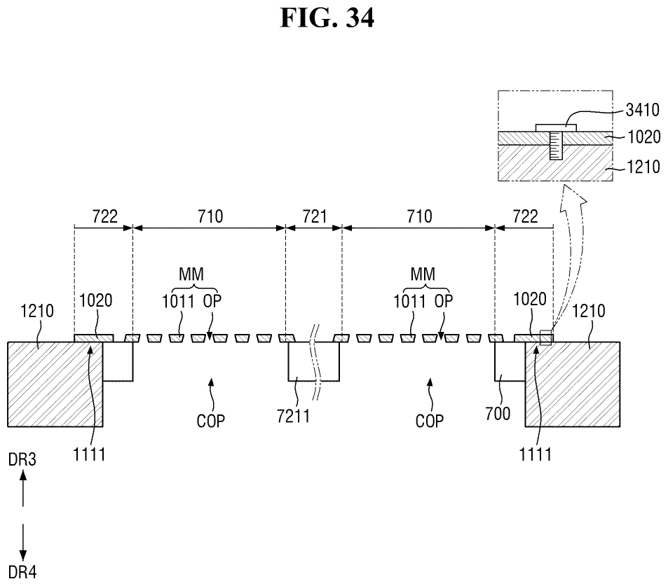

FIG. 34 is a conceptual view for describing a coupling of a first metal frame 1020 and a second metal frame 1210 using a screw.

The embodiment of FIG. 34 may be different from the embodiment of FIG. 13 in that the first metal frame 1020 and the second metal frame 1210 may be coupled using a screw 3410.

Referring to FIG. 34, in the mask MK according to an embodiment, the first metal frame 1020 may be disposed in the outer frame area 722 of the silicon substrate, and the first metal frame 1020 may be coupled to the second metal frame 1210, which is provided separately from the silicon substrate 700, using the screw 3410.

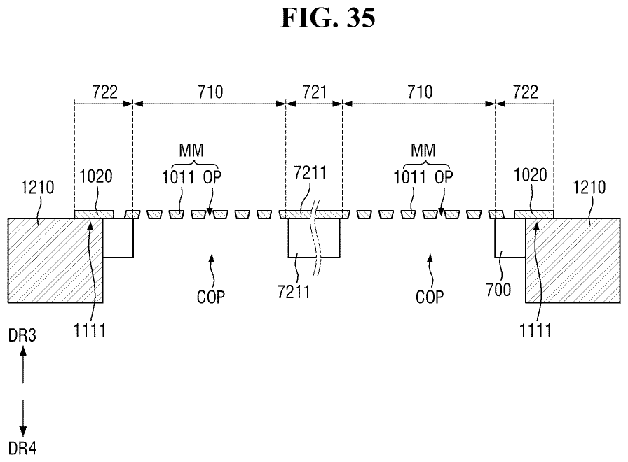

FIG. 35 is a schematic cross-sectional view of a mask in which the mask rip area 721 has a stacked structure of silicon and metal on silicon according to an embodiment.

The embodiment of FIG. 35 may be different from the embodiment of FIGS. 16 to 21 in that the mask rip 7211 may include a stacked structure of the silicon substrate 700 and a plating film formed on the silicon substrate 700.

Referring to FIG. 35, the mask MK according to an embodiment may include a mask membrane MM formed of a plating film, and a mask rip 7211 made of the same metal as the mask membrane MM and the silicon substrate 700 supporting the mask rip 7211 at the lower portion are disposed in the mask rip area 721. For example, in step 1630 of FIG. 16, the rear surface of the silicon substrate 700 corresponding to the mask rip area 721 is etched, but the rear surface of the silicon substrate 700 corresponding to the mask rip area 721 may be left without being etched. Accordingly, the mask rip 7211 according to an embodiment may include a stacked structure of the silicon substrate 700 and the plating film on the silicon substrate 700.

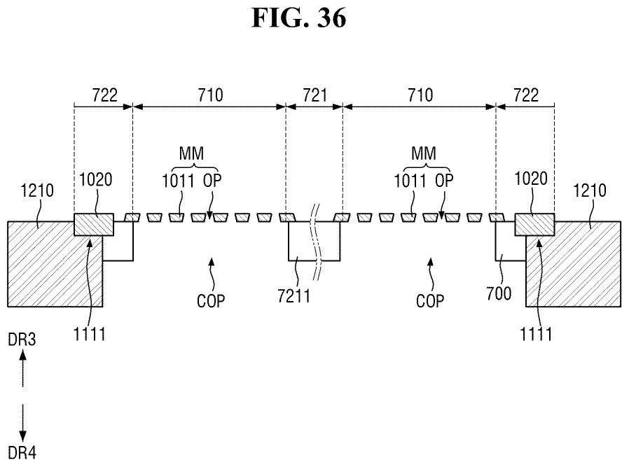

FIG. 36 is a schematic cross-sectional view of a mask for describing a thickness of the first metal frame 1020 according to an embodiment.

The embodiment of FIG. 36 may be different from the embodiment of FIGS. 8 to 21 in that the thickness of the first metal frame 1020 may be greater than the thickness of the mask membrane MM (for example, the thickness of the mask shadow 1011). According to an embodiment, the first metal frame 1020 and the second metal frame 1210 may be more readily welded.

Referring to FIG. 36, in the mask MK according to an embodiment, the first metal frame 1020 is disposed in the outer frame area 722, and the thickness of the first metal frame 1020 is greater than the thickness of the mask membrane MM (for example, the thickness of the mask shadow 1011). According to an embodiment, by increasing the thickness of the first metal frame 1020, a rigidity of the mask MK may be further increased and sagging of the mask may be reduced.

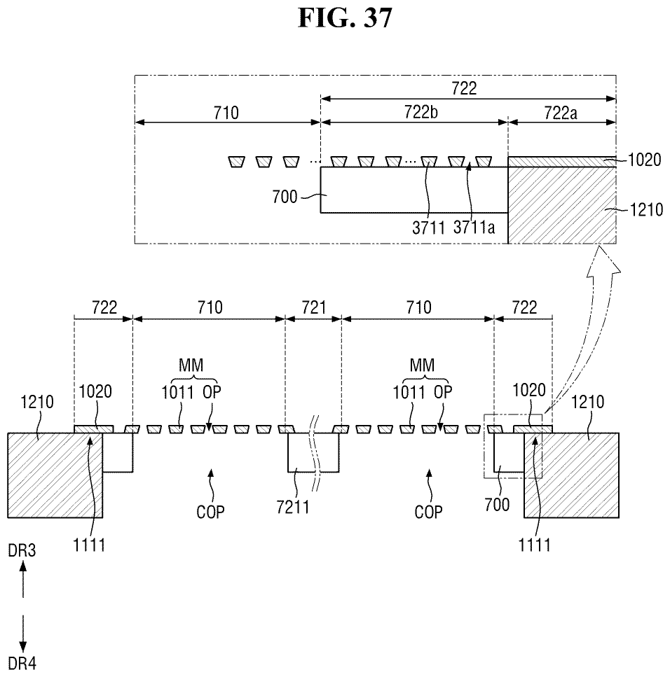

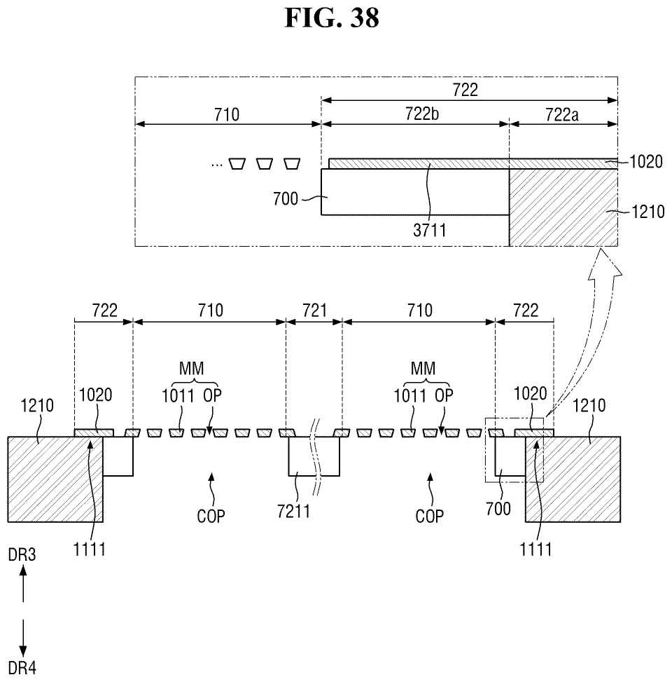

FIGS. 37 and 38 are schematic cross-sectional views of a mask illustrating a metal pattern disposed in a dummy frame area 722b between a first metal frame 1020 and an outermost cell area 710 according to an embodiment.

Referring to FIGS. 37 and 38, a dummy frame area 722b is defined between the first metal frame 1020 and the outermost cell area 710. For example, the outer frame area 722 may include a dummy frame area 722b adjacent to the outermost cell area 710, and an outermost frame area 722a disposed at an outer portion of the dummy frame area 722b and in which the first metal frame 1020 is formed. The outermost frame area 722a may be referred to as a first area, and the dummy frame area 722b may be referred to as a second area. For example, the outer frame area 722 may include a first area where the first metal frame 1020 is formed, and a second area disposed inside the first area and adjacent to the cell opening.

In the disclosure, the outermost cell area 710 refers to a cell area 710 disposed at the outermost portion among the cell areas 710 included in the mask MK. For example, the outermost cell area 710 may represent a cell area 710 adjacent to the outer frame area 722 among the cell areas 710.

According to an embodiment, as illustrated in FIG. 37, dummy metal patterns 3711 and 3711a may be formed in the dummy frame area 722b. The dummy metal patterns 3711 and 3711a may be disposed on the same layer as the mask membrane MM and the first metal frame 1020. For example, the dummy metal patterns 3711 and 3711a may be formed by the same plating process as the mask membrane MM and the first metal frame 1020. The dummy metal patterns 3711 and 3711a include dummy metals 3711 disposed at intervals in the dummy frame area 722b, and a dummy opening 3711a disposed between the dummy metals 3711.

The embodiment of FIG. 38 may be different from the embodiment of FIG. 37 in that a metal that is continuously connected without openings may be disposed in the dummy frame area 722b. For example, as illustrated in FIG. 38, a dummy metal 3711 that is continuously connected without being disconnected may be disposed between the first metal frame 1020 and the outermost cell area 710. The dummy metal 3711 according to an embodiment may be connected to the first metal frame 1020.

According to an embodiment of FIG. 37, unlike the embodiment of FIG. 38, by disposing the dummy metals 3711 and the dummy opening 3711a disposed between the dummy metals 3711 in the dummy frame area 722b, stress applied to the silicon substrate 700 may be reduced. For example, according to the embodiment of FIG. 37, as the dummy opening 3711a is disposed, sagging or distortion of the silicon substrate due to the stress applied to the silicon substrate 700 may be reduced as compared to the embodiment of FIG. 38.

Embodiments have been described hereinabove with reference to the accompanying drawings, but it will be understood by one of ordinary skill in the art to which the disclosure pertains that various modifications and alterations may be made without departing from the technical spirit or essential feature of the disclosure. Therefore, it should be understood that the embodiments described above are illustrative in all aspects and not restrictive.

In concluding the detailed description, those skilled in the art will appreciate that many variations and modifications can be made to the disclosed embodiments without substantially departing from the principles of the disclosure. Therefore, the disclosed embodiments are used in a generic and descriptive sense only and not for purposes of limitation.

What is claimed is:

1. A deposition mask comprising:
a silicon substrate including:
a plurality of cell areas;
a mask frame area excluding the plurality of cell areas, the mask frame area including a mask rip area partitioning the plurality of cell areas; and
an outer frame area disposed at an outermost portion of the silicon substrate;
a mask rip disposed in the mask rip area;
a mask membrane disposed in each of the plurality of cell areas;
a first metal frame disposed in the outer frame area; and
a second metal frame surrounding an outer portion of the silicon substrate and connected to the first metal frame.

2. The deposition mask of claim 1, wherein
the silicon substrate has a substantially circular shape in plan view, and
the second metal frame has a substantially ring shape surrounding the outer portion of the silicon substrate.

3. The deposition mask of claim 2, wherein
the silicon substrate includes a frame opening exposing a lower surface of the first metal frame in the outer frame area, and
the second metal frame is connected to the first metal frame through the frame opening.

4. The deposition mask of claim 3, wherein the first metal frame and the second metal frame are connected to each other by welding.

5. The deposition mask of claim 4, wherein a welded portion where the welding is performed is continuously connected along a perimeter of the second metal frame.

6. The deposition mask of claim 4, wherein a welded portion where the welding is performed is discontinuously connected along a perimeter of the second metal frame.

7. The deposition mask of claim 1, further comprising:
at least one metal sheet that crosses the silicon substrate,
wherein both ends of the metal sheet are each connected to the second metal frame.

8. The deposition mask of claim 7, wherein
the metal sheet extends along the mask rip area at a lower portion of the silicon substrate, and
the second metal frame includes a lower step portion on which the metal sheet is seated.

9. The deposition mask of claim 7, wherein
the metal sheet extends along the mask rip area at a lower portion of the silicon substrate, and
a groove into which the metal sheet is inserted is disposed on a side surface of the second metal frame.

10. The deposition mask of claim 7, wherein
the metal sheet extends along the mask rip area at an upper portion of the silicon substrate, and
the second metal frame includes an upper step portion on which the metal sheet is seated.

11. The deposition mask of claim 1, wherein a thickness of the first metal frame is greater than a thickness of the mask membrane.

12. The deposition mask of claim 1, wherein the mask membrane includes a plating film.

13. The deposition mask of claim 12, wherein the mask rip is formed as a portion of the silicon substrate.

14. The deposition mask of claim 12, wherein the mask rip includes a plating film formed by a same process as the mask membrane.

15. The deposition mask of claim 12, wherein the mask rip includes a stacked structure of a portion of the silicon substrate and a plating film formed by a same process as the mask membrane.

16. A method for manufacturing a deposition mask, the method comprising:
preparing a silicon substrate including a plurality of cell areas and a mask frame area excluding the plurality of cell areas, the mask frame area including a mask rip area partitioning the plurality of cell areas and an outer frame area disposed at an outermost portion of the silicon substrate;
forming a mask membrane and a first metal frame by performing a plating process;
forming a cell opening corresponding to the plurality of cell areas and a frame opening exposing a lower surface of the first metal frame by etching a rear surface of the silicon substrate;
aligning a second metal frame surrounding an outer portion of the silicon substrate with the silicon substrate; and
connecting the first metal frame and the second metal frame to each other.

17. The method of claim 16, wherein
the silicon substrate has a substantially circular shape in plan view, and
the second metal frame has a substantially ring shape surrounding the outer portion of the silicon substrate.

18. The method of claim 16, wherein the connecting of the first metal frame and the second metal frame to each other includes a welding process.

19. The method of claim 18, wherein a welded portion where the welding process is performed is continuously connected along a perimeter of the second metal frame.

20. The method of claim 18, wherein a welded portion where the welding process is performed is discontinuously connected along a perimeter of the second metal frame.
